(19) United States
(12) Patent Application Publication
(10) Pub. No.: US 2026/0011647 A1
(43) Pub. Date: Jan. 8, 2026

(54) OVERLAY VARIATION-RESISTANT FRAME LAYOUT AND METHODS FOR UTILIZING THE SAME DURING SEMICONDUCTOR MANUFACTURING

(71) Applicant: Taiwan Semiconductor Manufacturing Company Limited, Hsinchu (TW)

(72) Inventors: Jhih-Yu WANG, New Taipei City (TW); Hung-Jui KUO, Hsinchu (TW); Po-Han WANG, Hsinchu City (TW); Yan-Huei LEE, Hsinchu City (TW)

(21) Appl. No.: 18/764,462

(22) Filed: Jul. 5, 2024

(51) Int. Cl. H01L 23/538; H01L 21/56; H01L 23/00

(52) U.S. Cl. CPC H01L 23/5385; H01L 21/561; H01L 24/16; H01L 24/97; H01L 2224/16227; H01L 2224/97

(57) ABSTRACT

A reconstituted wafer is formed, which includes a two-dimensional array of interposer dies that are interconnected to one another and a two-dimensional array of semiconductor die sets. The two-dimensional array of interposer dies includes distal redistribution dielectric layers that are composed of dielectric negative photoresist materials and embed distal redistribution wiring interconnects. A lithographic exposure process sequentially lithographically exposes areas of the dielectric negative photoresist materials. Each illumination area includes an entirety of a laterally-sealed area enclosed by a respective edge seal ring structure, and further includes a respective adjacent kerf area such that a double-exposed area is formed between each neighboring pair of interposer dies.

### BACKGROUND

During the manufacturing of advanced package structures such as chip-on-wafer-on-substrate (CoWoS) packages and integrated fan-out (InFO) packages, the precision and uniformity of lithographic exposure in a stepper may impact the quality and performance of the resulting integrated package structures. The area of advanced package structures have faced challenges due to process variations inherent in the exposure equipment. One of the most persistent issues has been overlay variation, which occurs when there is a misalignment between the exposure fields during the various photolithography steps. This misalignment often leads to defects known as shot-to-shot mismatching. Such mismatches not only compromise the integrity of the resulting semiconductor device structures that are being manufactured but also increase the defect rates across the production batch. The resulting defects may manifest in various forms, including incomplete or excessive exposure of photoresist, leading to critical failures in the circuit patterns and potentially impacting the electrical functionality of the final products.

Additionally, these variations in overlay accuracy may be exacerbated by the stepping approach of the exposure tools, which sequentially expose different sections of the wafer. Each production step carries the potential for slight deviations from the intended alignment, accumulating discrepancies that may lead to large yield losses. This method is particularly problematic in advanced semiconductor manufacturing, where the tolerances for error are exceedingly low given the high density and complexity of the device architectures. As the industry continues to push towards smaller device geometries and more complex circuit designs, it is becoming increasingly important to provide a proper lithographic exposure pattern to package structures during the manufacturing process despite inherent overlay variations generated by the stepper in a lithographic exposure tool.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is top-down view of an exemplary structure including a first carrier wafer for forming a reconstituted wafer according to an embodiment of the present disclosure.

FIG. 2 is a vertical cross-sectional view of a region of the exemplary structure along the vertical plane X-X′ of FIG. 1 after disposing through-integrated-fan-out-via structures (TIV structures) on the first carrier wafer according to an embodiment of the present disclosure.

FIG. 3 is a vertical cross-sectional view of a region of the exemplary structure after disposing bridge dies on the first carrier wafer according to an embodiment of the present disclosure.

FIG. 4 is a vertical cross-sectional view of a local silicon interconnect (LIS) die according to an embodiment of the present disclosure.

FIG. 5 is a vertical cross-sectional view of a region of the exemplary structure after formation of a core-level molding compound matrix according to an embodiment of the present disclosure.

FIG. 6 is a vertical cross-sectional view of a region of the exemplary structure after planarizing the core-level molding compound matrix according to an embodiment of the present disclosure.

FIG. 7 is a vertical cross-sectional view of a region of the exemplary structure after formation of proximal redistribution dielectric layers, proximal redistribution wiring interconnects, and proximal bump structures according to an embodiment of the present disclosure.

FIG. 8 is a vertical cross-sectional view of a region of the exemplary structure after attaching semiconductor dies to the proximal bump structures according to an embodiment of the present disclosure.

FIG. 9 is a vertical cross-sectional view of a region of the exemplary structure after formation of die-interposer underfill material portions according to an embodiment of the present disclosure.

FIG. 10 is a vertical cross-sectional view of a region of the exemplary structure after formation of a die-level molding compound matrix according to an embodiment of the present disclosure.

FIG. 11 is a vertical cross-sectional view of a region of the exemplary structure after planarizing the die-level molding compound matrix and after attaching a second carrier wafer to the die-level molding compound matrix according to an embodiment of the present disclosure.

FIG. 12 is a vertical cross-sectional view of a region of the exemplary structure after detaching the first carrier wafer according to an embodiment of the present disclosure.

FIG. 13 is a vertical cross-sectional view of a region of the exemplary structure after formation of distal redistribution dielectric layers and distal redistribution wiring interconnects according to an embodiment of the present disclosure.

FIG. 14 is a top-down view of the exemplary structure after lithographically exposing a first subset of the organic interposer dies in a reconstituted wafer according to an embodiment of the present disclosure. The vertical plane X-X′ corresponds to the cut plane of the vertical cross-sectional view of FIG. 13.

FIG. 15A is a schematic top-down view of a region around a selected organic interposer die that illustrates the lithographic illumination area within an exposure field relative to the selected organic interposer die in embodiments in which a first lithographic exposure pattern is used in each lithographic exposure according to an embodiment of the present disclosure.

FIG. 15B is a schematic top-down view of a region around a selective organic interposer die after sequentially lithographically exposing a subset of the organic interposer dies up to the selected organic interposer die in embodiments in which the first lithographic exposure pattern is used in each lithographic exposure according to an embodiment of the present disclosure.

FIG. 16A is a schematic top-down view of a region around a selected organic interposer die that illustrates the lithographic illumination area within an exposure field relative to the selected organic interposer die in embodiments in which a second lithographic exposure pattern is used in each lithographic exposure according to an embodiment of the present disclosure.

FIG. 16B is a schematic top-down view of a region around a selective organic interposer die after sequentially lithographically exposing a subset of the organic interposer dies up to the selected organic interposer die in embodiments in which the second lithographic exposure pattern is used in each lithographic exposure according to an embodiment of the present disclosure.

FIG. 17A is a schematic top-down view of a region around a selected organic interposer die that illustrates the lithographic illumination area within an exposure field relative to the selected organic interposer die in embodiments in which a third lithographic exposure pattern is used in each lithographic exposure according to an embodiment of the present disclosure.

FIG. 17B is a schematic top-down view of a region around a selective organic interposer die after sequentially lithographically exposing a subset of the organic interposer dies up to the selected organic interposer die in embodiments in which the third lithographic exposure pattern is used in each lithographic exposure according to an embodiment of the present disclosure.

FIG. 18A is a schematic top-down view of a region around a selected organic interposer die that illustrates the lithographic illumination area within an exposure field relative to the selected organic interposer die in embodiments in which a fourth lithographic exposure pattern is used in each lithographic exposure according to an embodiment of the present disclosure.

FIG. 18B is a schematic top-down view of a region around a selective organic interposer die after sequentially lithographically exposing a subset of the organic interposer dies up to the selected organic interposer die in embodiments in which the fourth lithographic exposure pattern is used in each lithographic exposure according to an embodiment of the present disclosure.

FIG. 19A is a schematic top-down view of a region around a selected organic interposer die that illustrates the lithographic illumination area within an exposure field relative to the selected organic interposer die in embodiments in which a fifth lithographic exposure pattern is used in each lithographic exposure according to an embodiment of the present disclosure.

FIG. 19B is a schematic top-down view of a region around a selective organic interposer die after sequentially lithographically exposing a subset of the organic interposer dies up to the selected organic interposer die in embodiments in which the fifth lithographic exposure pattern is used in each lithographic exposure according to an embodiment of the present disclosure.

FIG. 20A is a schematic top-down view of a region around a selected organic interposer die that illustrates the lithographic illumination area within an exposure field relative to the selected organic interposer die in embodiments in which a sixth lithographic exposure pattern is used in each lithographic exposure according to an embodiment of the present disclosure.

FIG. 20B is a schematic top-down view of a region around a selective organic interposer die after sequentially lithographically exposing a subset of the organic interposer dies up to the selected organic interposer die in embodiments in which the sixth lithographic exposure pattern is used in each lithographic exposure according to an embodiment of the present disclosure.

FIG. 21A is a vertical cross-sectional view of a region of the exemplary structure after development of the distal redistribution dielectric layers according to an embodiment of the present disclosure.

FIG. 21B is a magnified view of a region of the vertical cross-sectional view of FIG. 21A.

FIG. 21C is a schematic vertical cross-sectional view of a region of the distal redistribution dielectric layers of FIG. 21A.

FIG. 21D is an additional vertical cross-sectional view for some configurations of the exemplary structure after development of the distal redistribution dielectric layers according to an embodiment of the present disclosure.

FIG. 21E is a magnified view of a region of the vertical cross-sectional view of FIG. 21D.

FIG. 21F is a schematic vertical cross-sectional view of a region of the distal redistribution dielectric layers of FIG. 21D.

FIG. 22A is a vertical cross-sectional view of a region of the exemplary structure after formation of distal bump structures and solder material portions according to an embodiment of the present disclosure.

FIG. 22B is a magnified view of a region of the vertical cross-sectional view of FIG. 22A.

FIG. 22C is an additional vertical cross-sectional view for some configurations of the exemplary structure after formation of distal bump structures and solder material portions according to an embodiment of the present disclosure.

FIG. 22D is a magnified view of a region of the vertical cross-sectional view of FIG. 21C.

FIG. 23 is a vertical cross-sectional view of a region of the exemplary structure after attaching a backside support tape according to an embodiment of the present disclosure.

FIG. 24 is a vertical cross-sectional view of a region of the exemplary structure after detaching the second carrier wafer according to an embodiment of the present disclosure.

FIG. 25A is a vertical cross-sectional view of an exemplary composite die according to an embodiment of the present disclosure.

FIG. 25B is an additional vertical cross-sectional view for some configurations of the exemplary composite die according to an embodiment of the present disclosure.

FIG. 26 is a vertical cross-sectional view of an exemplary assembly of a composite die and a packaging substrate according to an embodiment of the present disclosure.

FIG. 27 is a vertical cross-sectional view of the exemplary assembly after attaching a heat sink structure according to an embodiment of the present disclosure.

FIG. 28 is a vertical cross-sectional view of the exemplary assembly after attaching solder joints according to an embodiment of the present disclosure.

FIG. 29A is a vertical cross-sectional view of the exemplary structure after attachment to a printed circuit board.

FIG. 29B is an additional vertical cross-sectional view for some configurations of the exemplary structure after attachment to a printed circuit board.

FIG. 30 is a first flowchart illustrating steps for forming a device structure according to an embodiment of the present disclosure.

FIG. 31 is a second flowchart illustrating steps for forming a device structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Embodiments of the present disclosure are directed to methods for preventing formation of undesirable trenches in distal redistribution dielectric layers within organic interposer dies, which may be due to overlap variations during lithographic exposure of the distal redistribution dielectric layers. The distal redistribution dielectric layers comprise negative photoresist materials, and lack of irradiation by light during exposure may cause an absence of cross-linking to and from molecules of the negative photoresist materials, and subsequently, formation of undesirable trenches upon development of the negative photoresist material. Embodiments of the present disclosure provide enhanced frame layouts in which the lithographically irradiated areas are configured to eliminate, or minimize, unirradiated areas upon completion of lithographic exposure of all dies. The distal redistribution dielectric layers may be formed with less topographical defects, and manufacturing yield and reliability of organic interposer dies may be enhanced. Various aspects of embodiments of the present disclosure are now described with reference to accompanying figures.

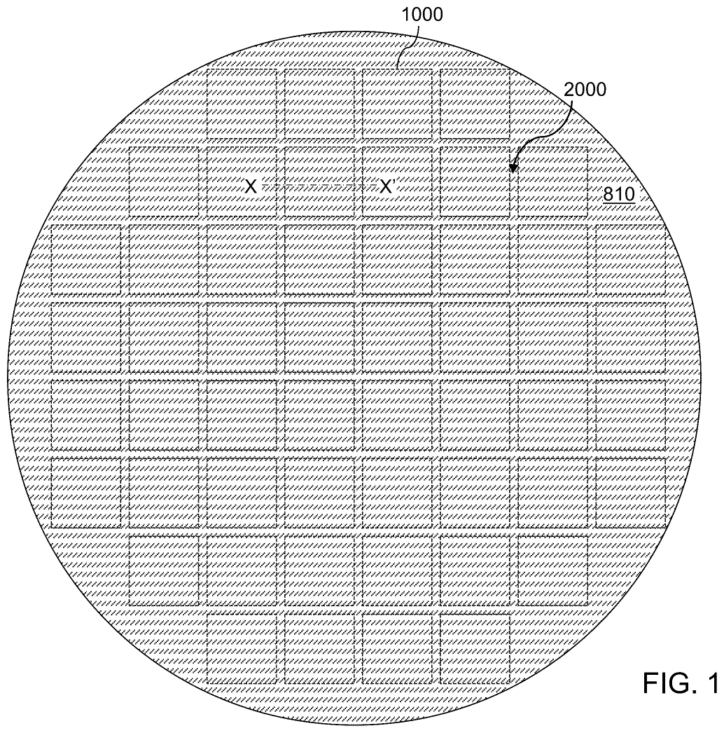

Referring to FIG. 1, an exemplary structure including a first carrier wafer 810 for forming a reconstituted wafer is illustrated. The first carrier wafer 810 may include an optically transparent substrate such as a glass substrate or a sapphire substrate, or may comprise a semiconductor substrate such as a silicon substrate. The diameter of the first carrier wafer 810 may be in a range from 150 mm to 450 mm, although lesser and greater diameters may be used. The thickness of the first carrier wafer 810 may be in a range from 500 microns to 2,000 microns, although lesser and greater thicknesses may also be used. Alternatively, the first carrier wafer 810 may be provided in a rectangular panel format.

The first carrier wafer 810 comprise a two-dimensional rectangular array of die pattern areas 1000 in which composite dies are to be subsequently formed. As used herein, a composite die refers to a die that includes at least one semiconductor die and additional structural components that are attached to the at least one semiconductor die to provide a package structure. Each die pattern area 1000 may be defined by an outermost periphery of a respective edge ring seal structure to be subsequently formed. The areas between neighboring pairs of die pattern areas 1000 are used to build kerf structures (i.e., structures that are not incorporated into a functional set of components within a composite die), and are herein referred to as kerf areas 2000. Kerf is the width of material that is removed by a cutting process, such as saw or cutting torch. The kerf may also refer to the gap or slot created by the cutting tool as the cutting tool removes material from the workpiece. A thin central strip region of each kerf area 2000 is used as a dicing channel, which has a width in a range from 80 microns to 500 microns, although lesser and greater widths may also be used. The width of each kerf area 2000 is wider than the width of a dicing channel by a dimension in a range from 160 nm to 1 mm, such as from 200 nm to 600 nm, although lesser and greater dimensions may also be used.

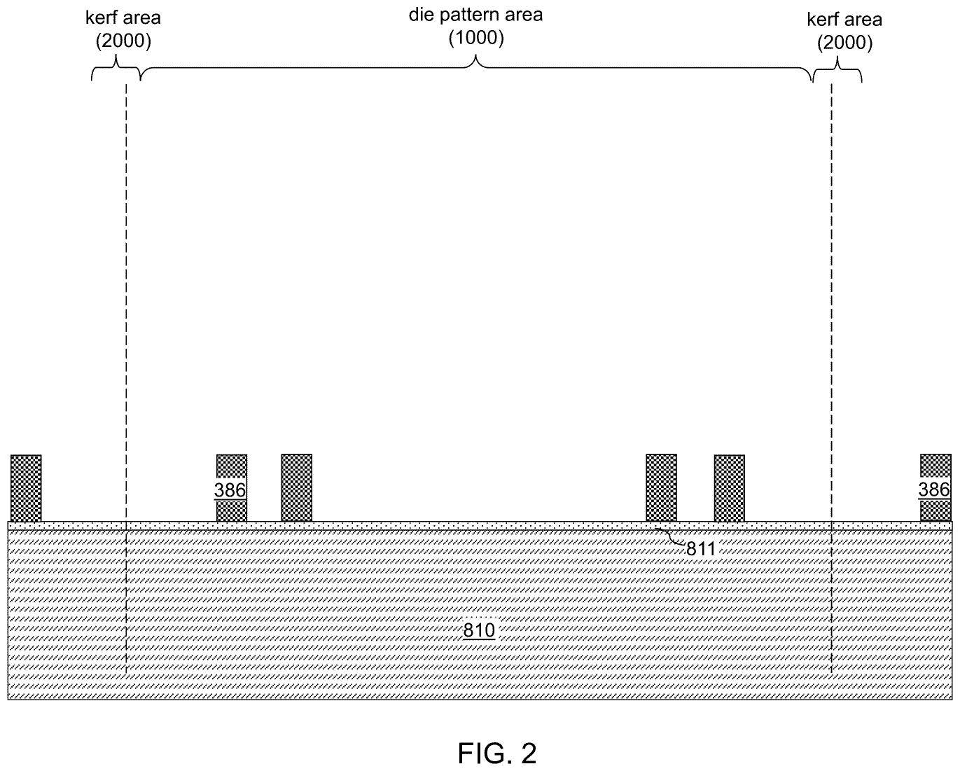

Referring to FIG. 2, a first adhesive layer 811 may be applied to a front-side surface of the first carrier wafer 810. In one embodiment, the first adhesive layer 811 may be a light-to-heat conversion (LTHC) layer. Alternatively, the first adhesive layer 811 may include a thermally decomposing adhesive material.

A set of conductive pillar structures, such as a set of metallic pillar structures, may be attached to the first adhesive layer 811 within each die pattern area 1000. The conductive pillar structures are herein referred to as through-integrated-fan-out-via (TIV) structures 386, and may be positioned in areas that do not overlap with areas of bridge dies to be subsequently disposed on the first adhesive layer 811. Each TIV structure 386 may consist of at least one metallic material, such as tungsten or copper and optionally a metallic barrier material (such as TiN, TaN, WN, and/or MoN), and may have a shape of a cylinder. The diameter of each TIV structure 386 may be in a range from 30 microns to 300 microns, such as from 60 microns to 200 microns, although lesser and greater diameters may also be used. The height of each TIV structure 386 may be in a range from 10 microns to 100 microns, such as from 15 microns to 50 microns, although lesser and greater heights may also be used.

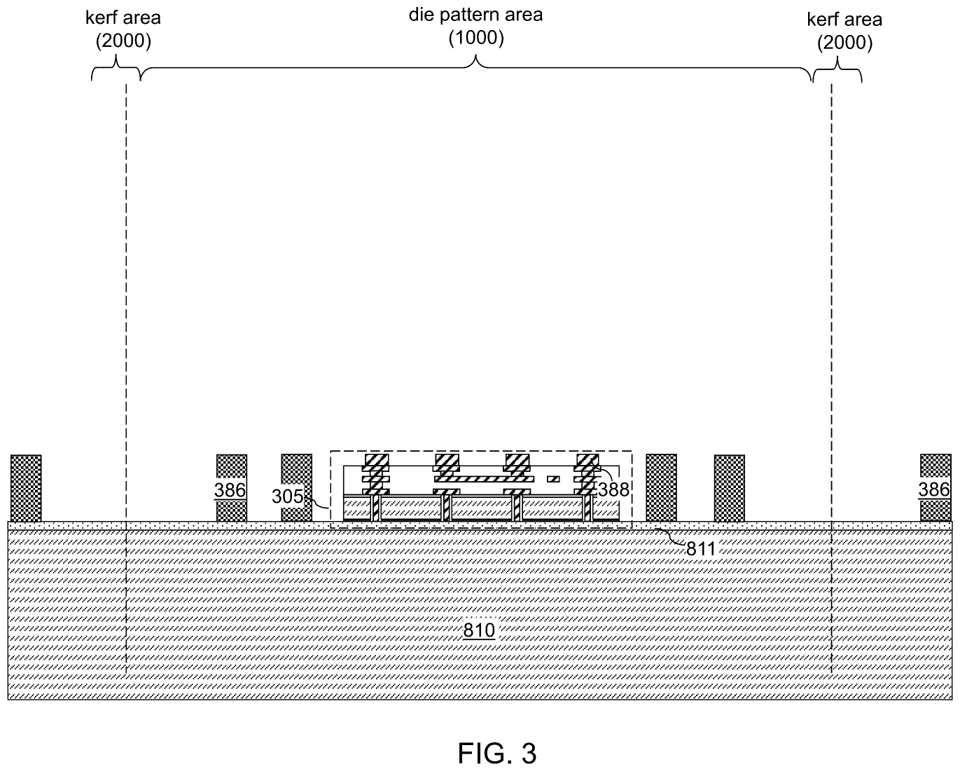

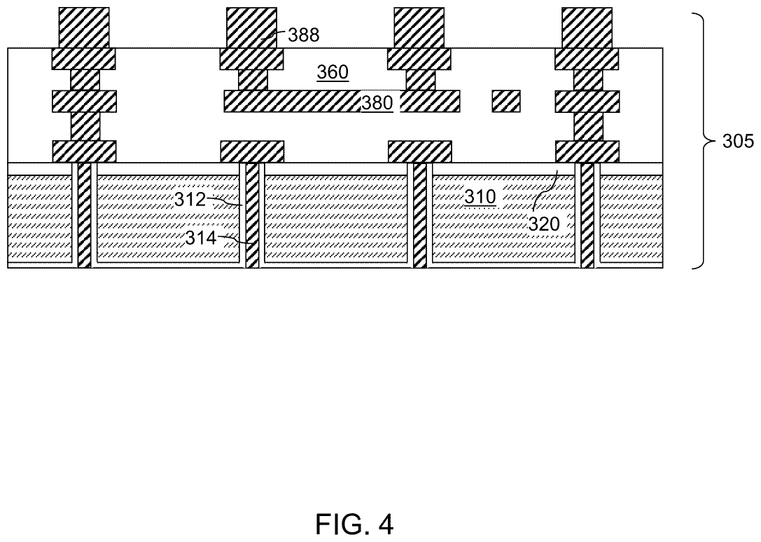

Referring to FIGS. 3 and 4, at least one bridge die 305 may be disposed over the first carrier wafer 810 (e.g., on a top surface of the first adhesive layer 811) in each die pattern area 1000. The bridge dies 305 may comprise local silicon interconnect (LSI) dies as known in the art. In one embodiment, each bridge die 305 may include a silicon substrate 310 (as thinned and diced during manufacturing of the bridge die 305), through-substrate openings that vertically extend through the silicon substrate 310, a dielectric liner 312 that provides electrical isolation for through-silicon via structures 314, a planar dielectric material layer 320, and metal interconnect structures 380 formed within dielectric material layers 360 and electrically connected to the through-silicon via structures 314 and/or electrically connected thereamongst. Bridge-die metal pads 388 may be provided on the topmost metal interconnect structures 380. Optionally, a subset of the metal interconnect structures 380 may provide electrical connection to and from a subset of the bridge-die metal pads 388 to provide electrically conductive path. Another subset of the metal interconnect structures 380 may be electrically connected to a respective one of the through-silicon via structures 314. The through-silicon via structures 314 or the bridge-die metal pads 388 may be disposed on the top surface of the first adhesive layer 811.

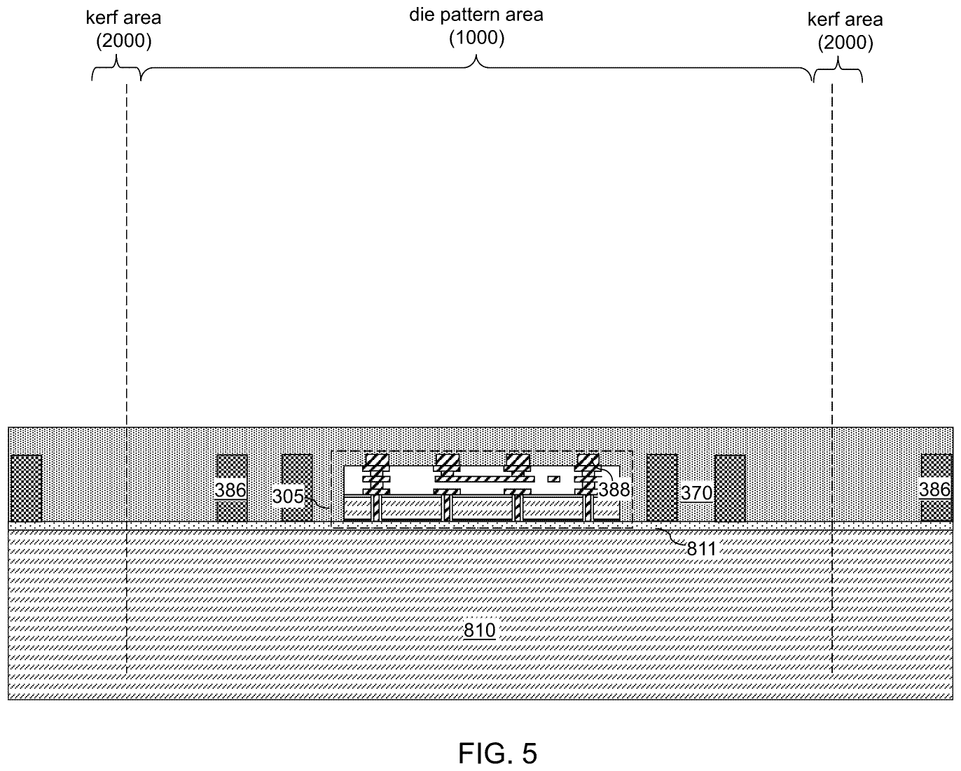

Referring to FIG. 5, a molding compound (MC) may be applied to the gaps between the bridge dies 305 and the TIV structures 386. The MC includes an epoxy-containing compound that may be hardened (i.e., cured) to provide a dielectric material portion having sufficient stiffness and mechanical strength. In one embodiment, the MC includes a first non-photosensitive molding compound material. The MC may include epoxy resin, hardener, silica (as a filler material), and other additives. The MC may be provided in a liquid form or in a solid form depending on the viscosity and flowability. Liquid MC typically provides better handling, good flowability, less voids, better fill, and less flow marks. Solid MC typically provides less cure shrinkage, better stand-off, and less die drift. A high filler content (such as 85% in weight) within an MC may shorten the time in mold, lower the mold shrinkage, and reduce the mold warpage. Uniform filler size distribution in the MC may reduce flow marks, and may enhance flowability. The exemplary structure comprises a reconstituted wafer in which a plurality of bridge dies 305 are incorporated within layer of the MC.

The MC may be cured at a curing temperature to form an MC matrix, which is herein referred to as a first molding compound matrix or a core-level molding compound matrix 370. A reconstituted wafer is formed, which comprises the core-level molding compound matrix 370, a two-dimensional array of bridge dies 305, and a two-dimensional array of sets of TIV structures 386. The core-level molding compound matrix 370 laterally encloses each of the bridge dies 305 and the TIV structures 386. The core-level molding compound matrix 370 may be a continuous material layer that extends across the entirety of the area of the reconstituted wafer and overlies the first carrier wafer 810.

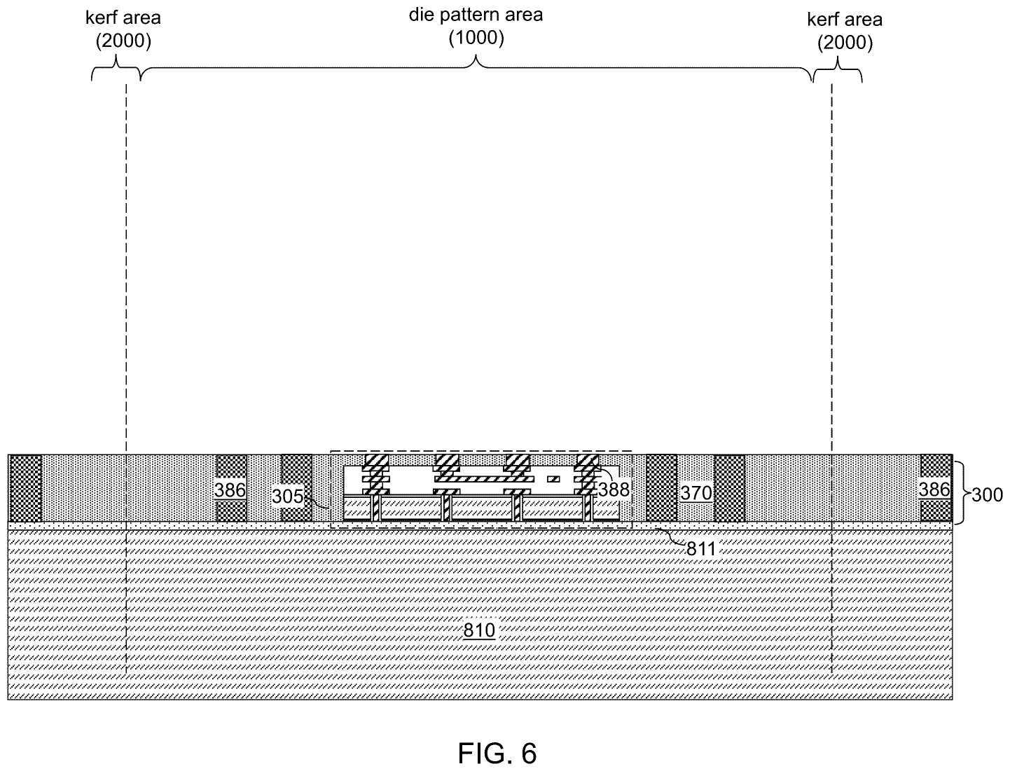

Referring to FIG. 6, the core-level molding compound matrix 370 may be planarized. For example, a chemical mechanical polishing (CMP) process may be performed to remove excess portions of the core-level molding compound matrix 370 from above the horizontal plane including the top surfaces of the bridge die 305 and the TIV structures 386. Surfaces of the through-silicon via structures 314 and the bridge-die metal pads 388 may be physically exposed after the planarization process. In one embodiment, the first molding compound matrix 370 comprises a first non-photosensitive molding compound material. Generally, the reconstituted wafer may comprise an interposer core layer 300 comprising at least one of a two-dimensional array of bridge dies 305, and a two-dimensional array of sets of through-integrated-fan-out-via (TIV) structures 386. In the illustrated example, the reconstituted wafer comprises an interposer core layer 300 comprising a two-dimensional array of bridge dies 305 and a two-dimensional array of sets of through-integrated-fan-out-via (TIV) structures 386.

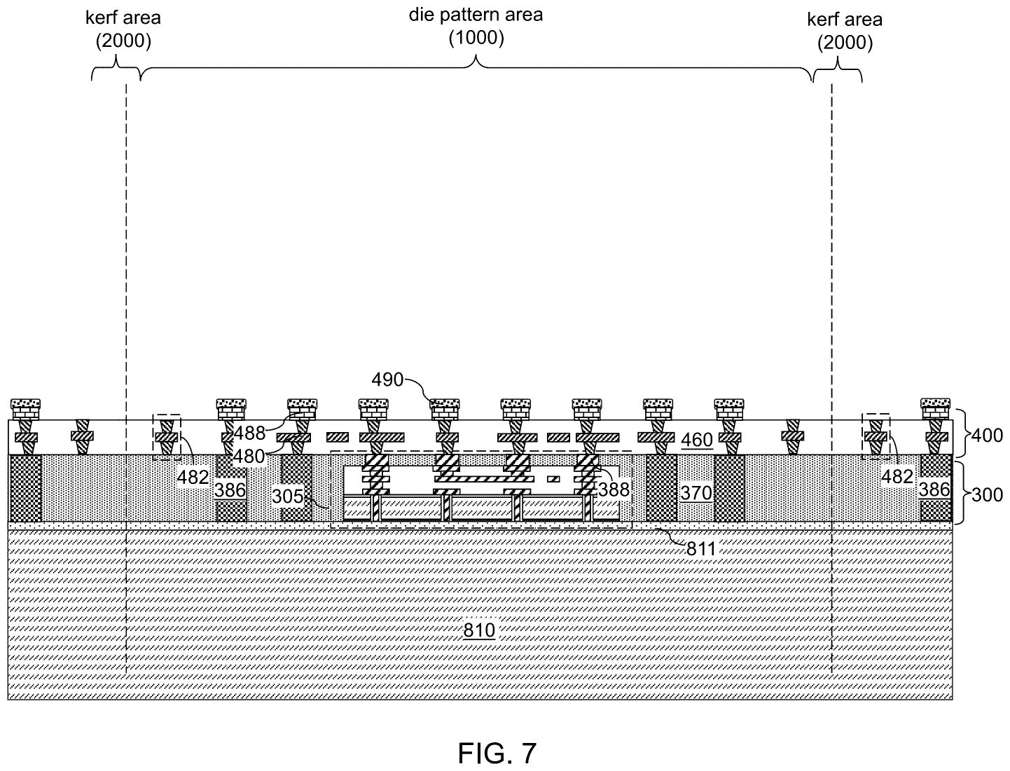

Referring to FIG. 7, a two-dimensional array of proximal redistribution structures 400 (which are also referred to as die-side redistribution structures or first redistribution structures) may be formed over the interposer core layer 300. Semiconductor dies are subsequently attached to the proximal redistribution structures 400, and thus, the proximal redistribution structures 400 are more proximal to the semiconductor dies than additional redistribution structures (which are also referred to as distal redistribution structures) that are subsequently formed. Each proximal redistribution structure 400 is formed within the area of a respective die pattern area 1000.

The proximal redistribution structures 400 may include proximal redistribution dielectric layers 460, proximal redistribution wiring interconnects 480, and proximal bump structures 488. The proximal redistribution dielectric layers 460 are also referred to as first redistribution dielectric layers. The proximal redistribution dielectric layers 460 include a respective dielectric polymer material such as polyimide (PI), benzocyclobutene (BCB), or polybenzobisoxazole (PBO). Each proximal redistribution dielectric layer 460 may be formed by spin coating and drying of the respective dielectric polymer material. The thickness of each proximal redistribution dielectric layer 460 may be in a range from 2 microns to 40 microns, such as from 4 microns to 20 microns. Each proximal redistribution dielectric layer 460 may be patterned, for example, by applying and patterning a respective photoresist layer thereabove, and by transferring the pattern in the photoresist layer into the proximal redistribution dielectric layer 460 using an etch process such as an anisotropic etch process. The photoresist layer may be subsequently removed, for example, by ashing.

The proximal redistribution wiring interconnects 480 may be formed within the proximal redistribution dielectric layers. The proximal redistribution wiring interconnects 480 may also referred to as second redistribution wiring interconnects. Each of the proximal redistribution wiring interconnects 480 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 300 nm, and the copper seed layer may have a thickness in a range from 100 nm to 500 nm. The metallic fill material for the proximal redistribution wiring interconnects 480 may include copper, nickel, or copper and nickel. The thickness of the metallic fill material that is deposited for each proximal redistribution wiring interconnect 480 may be in a range from 2 microns to 40 microns, such as from 4 microns to 10 microns, although lesser or greater thicknesses may also be used. The total number of levels of wiring in each proximal redistribution structure 400 (i.e., the levels of the proximal redistribution wiring interconnects 480) may be in a range from 1 to 10, although number of levels of wiring may also be used. According to an embodiment of the present disclosure, a subset of the proximal redistribution wiring interconnect 480 may comprise edge seal ring structure 482. Each edge seal ring structure may comprise a contiguous vertical stack of at least one annular metal via structure and at least one annular metal line structure that forms a continuous wall structure that laterally encloses all other proximal redistribution wiring interconnects 480 within a respective die pattern area 1000. Each die pattern area 1000 may be defined by the outermost periphery of an edge seal ring structure as seen in a plan view, such as a top-down view.

The proximal bump structures 488 are bump structures that are subsequently used to bond with semiconductor dies. The proximal bump structures 488 may comprise copper. The proximal bump structures 488 may have horizontal cross-sectional shapes of rectangles, rounded rectangles, or circles. Other cross-sectional shapes may be within the contemplated scope of disclosure. Typically, the proximal bump structures 488 may be configured for microbump bonding, and may have a height in a range from 5 microns to 50 microns, although lesser or greater heights may also be used. In one embodiment, the proximal bump structures 488 may be formed as an array of microbumps (such as copper pillars) having a lateral dimension in a range from 10 microns to 50 microns, and having a pitch in a range from 20 microns to 100 microns. Die-side solder material portions 490 may be formed on the proximal bump structures 488.

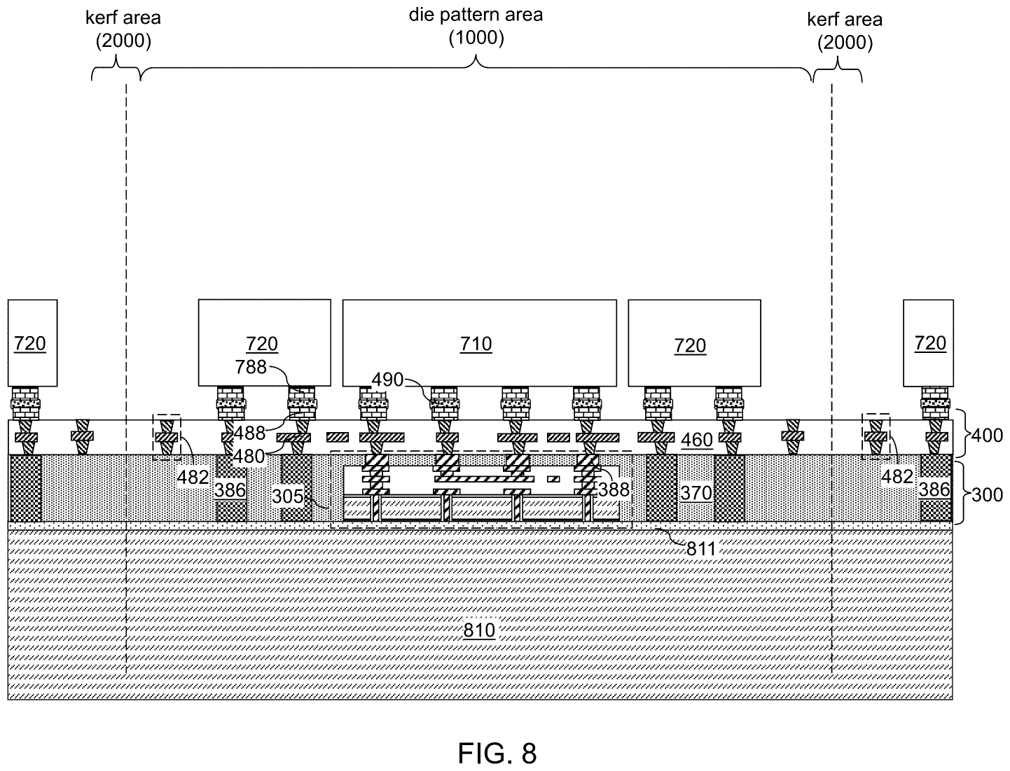

Referring to FIG. 8, a set of at least one semiconductor die (710, 720) may be bonded to a set of proximal bump structures 488 in each die pattern area 1000. Each set of at least one semiconductor die (710, 720) may include any set of semiconductor dies known in the art. In one embodiment, each set of at least one semiconductor die (710, 720) may include at least one system-on-chip (SoC) die 710 and/or at least one memory die 720. Optionally, each set of at least one semiconductor die (710, 720) may include at least one surface mount die known in the art. Each SoC die 710 may comprise an application processor die, a central processing unit die, or a graphic processing unit die. In one embodiment, the at least one memory die 720 may comprise a high bandwidth memory (HBM) die that includes a vertical stack of static random access memory dies. In one embodiment, the at least one semiconductor die (710, 720) may include at least one system-on-chip (SoC) die 710 and at least one high bandwidth memory (HBM) die. Each HBM die may comprise a vertical stack of static random access memory (SRAM) dies that are interconnected to one another through arrays of microbumps and are laterally surrounded by a respective molding material enclosure frame.

Each semiconductor die (710, 720) may comprise a respective array of on-die bump structures 788. Each of the at least one semiconductor die (710, 720) may be positioned in a face-down position such that on-die bump structures 788 face the die-side solder material portions 490. Placement of the at least one semiconductor die (710, 720) may be performed using a pick and place apparatus such that each of the on-die bump structures 788 may face a respective one of the die-side solder material portions 490.

In one embodiment, the on-die bump structures 788 and the proximal bump structures 488 may be configured for microbump bonding. In this embodiment, each of the on-die bump structures 788 and the proximal bump structures 488 may be configured as copper pillar structures having a diameter in a range from 10 microns to 50 microns, and may have a respective height in a range from 5 microns to 50 microns. The pitch of the microbumps in the direction of periodicity may be in a range from 20 microns to 100 microns, although lesser and greater pitches may also be used. Upon reflow, the lateral dimensions of each die-side solder material portion 490 may be in a range from 100% to 150% of the lateral dimension (such as a diameter) of the adjoined on-die bump structure 788 or of the adjoined proximal bump structure 488.

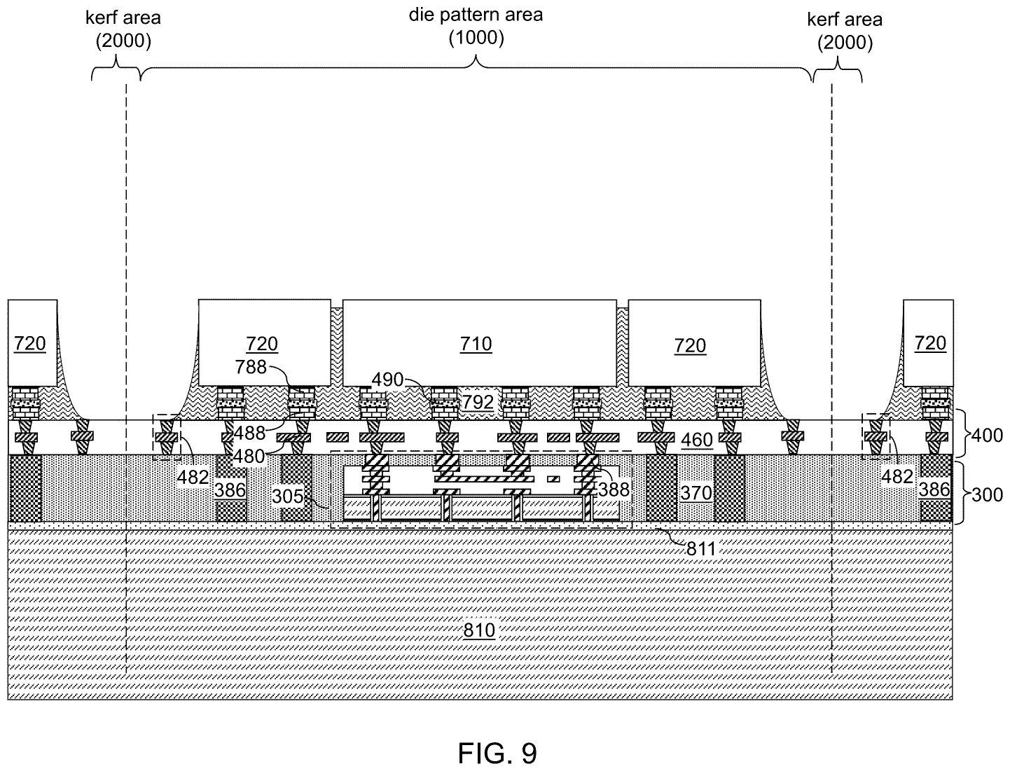

Referring to FIG. 9, a die-side underfill material may be applied into each gap between the proximal redistribution structures 400 and sets of at least one semiconductor die (710, 720) that are bonded to the proximal redistribution structures 400. The die-side underfill material may comprise any underfill material known in the art. A die-interposer underfill material portion 792 may be formed within each die pattern area 1000 between a proximal redistribution structure 400 and an overlying set of at least one semiconductor die (710, 720). Each die-interposer underfill material portions 792 may be formed by injecting the proximal underfill material around a respective array of die-side solder material portions 490 in a respective die pattern area 1000. Any known underfill material application method may be used, which may be, for example, the capillary underfill method, the molded underfill method, or the printed underfill method.

In one embodiment, a plurality of semiconductor dies (710, 720) may be attached to a proximal redistribution structure 400 through a respective array of solder material portions 490.

Within each die pattern area 1000, a die-interposer underfill material portion 792 may laterally surround, and contact, a respective set of the die-side solder material portions 490. Each die-interposer underfill material portion 792 may be formed around, and contact, die-side solder material portions 490, proximal bump structures 488, and on-die bump structures 788 in a respective die pattern area 1000. Generally, at least one semiconductor die (710, 720) comprising a respective set of on-die bump structures 788 is attached to the proximal bump structures 488 through a respective set of die-side solder material portions 490 within each die pattern area 1000. Within each die pattern area 1000, a die-interposer underfill material portion 792 laterally surrounds the proximal bump structures 488 and the on-die bump structures 788 of the at least one semiconductor die (710, 720).

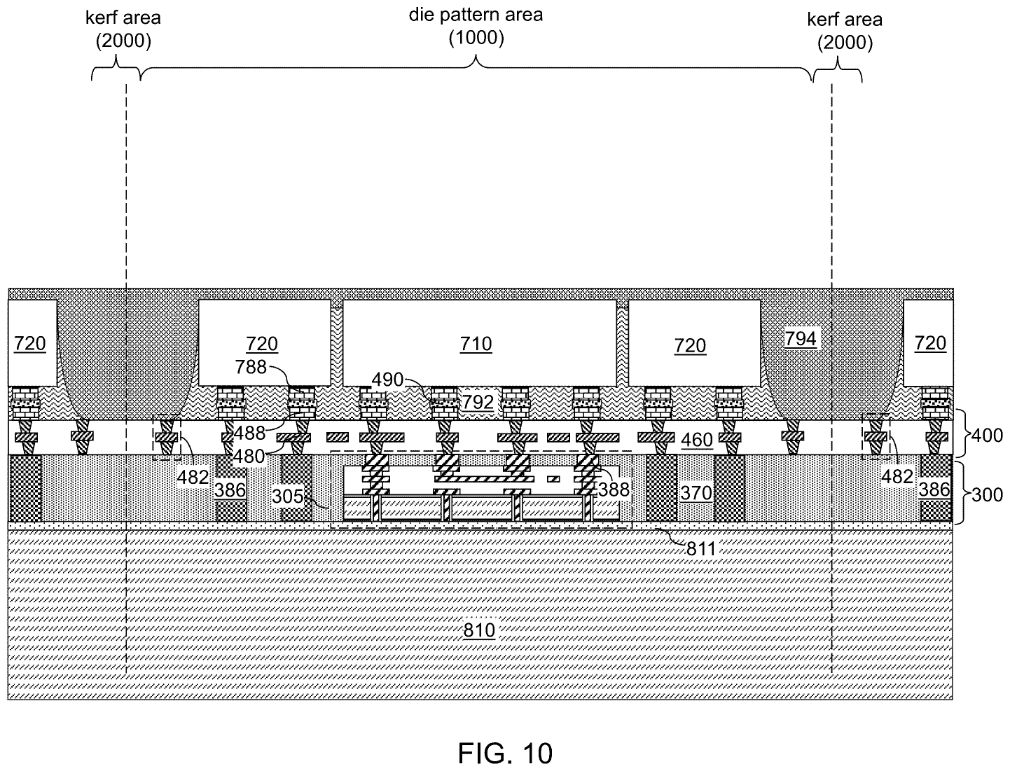

Referring to FIG. 10, a molding compound (MC) may be applied to the gaps between assemblies of a respective set of at least one semiconductor die (710, 720) and a respective die-interposer underfill material portion 792. The MC may include any material that may be used for the core-level molding compound matrix 370 discussed above. The MC may include epoxy resin, hardener, silica (as a filler material), and other additives. The MC may be cured at a curing temperature to form an MC matrix, which is herein referred to as a die-level molding compound matrix 794, which is also referred to as a second molding compound matrix. The die-level molding compound matrix 794 laterally surrounds and embeds each assembly of a set of at least one semiconductor die (710, 720) and a die-interposer underfill material portion 792. In one embodiment, the die-level molding compound matrix 794 comprises a second non-photosensitive molding compound material.

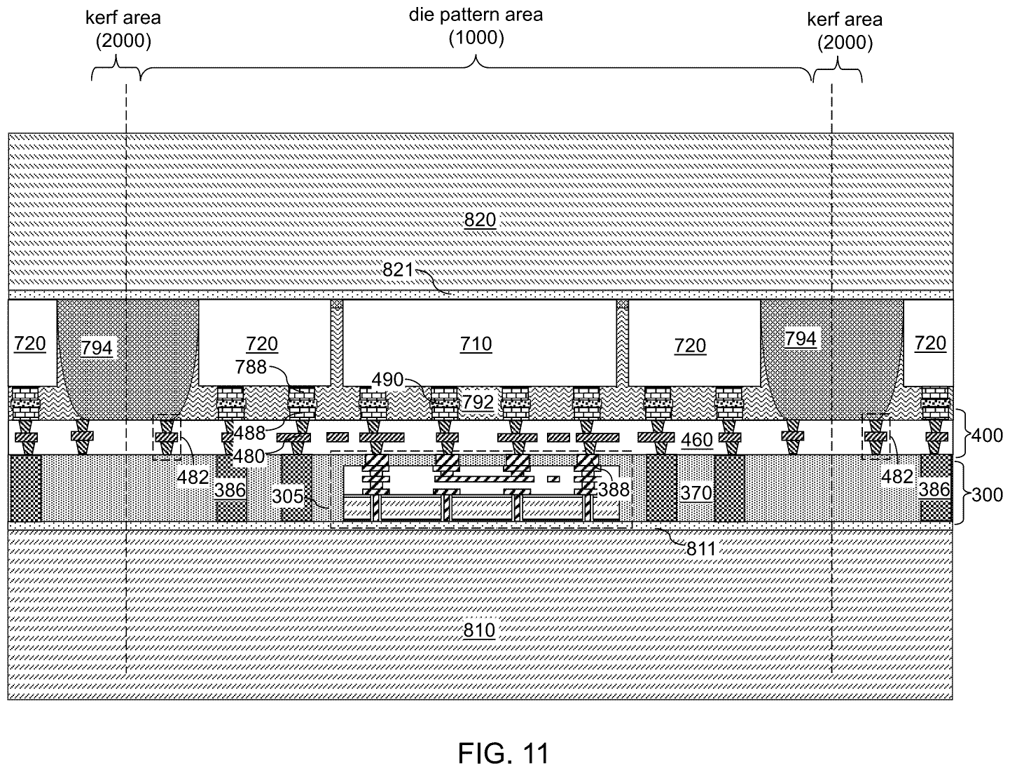

Referring to FIG. 11, portions of the die-level molding compound matrix 794 that overlies the horizontal plane including the top surfaces of the at least one semiconductor die (710, 720) may be removed by a planarization process. For example, the portions of the die-level MC matrix that overlies the horizontal plane may be removed using a chemical mechanical planarization (CMP). The reconstituted wafer that overlies the first carrier wafer 810 comprises a combination of the interposer core layer 300, a two-dimensional array of proximal redistribution structures 400, a two-dimensional array of sets of at least one semiconductor die (710, 720), a two-dimensional array of die-interposer underfill material portions 792, and the die-level molding compound matrix 794.

A second adhesive layer 821 may be applied over the two-dimensional array of sets of at least one semiconductor die (710, 720) and the die-level molding compound matrix 794. The second adhesive layer 821 may comprise a light-to-heat conversion (LTHC) layer or a thermally decomposing adhesive material layer depending on the removal mechanism to be subsequently used. A second carrier wafer 820 may be attached to the die-level molding compound matrix 794 through the second adhesive layer 821. The second carrier wafer 820 may comprise any material that may be used for the first carrier wafer 810, and generally may have about the same thickness range as the first carrier wafer 810.

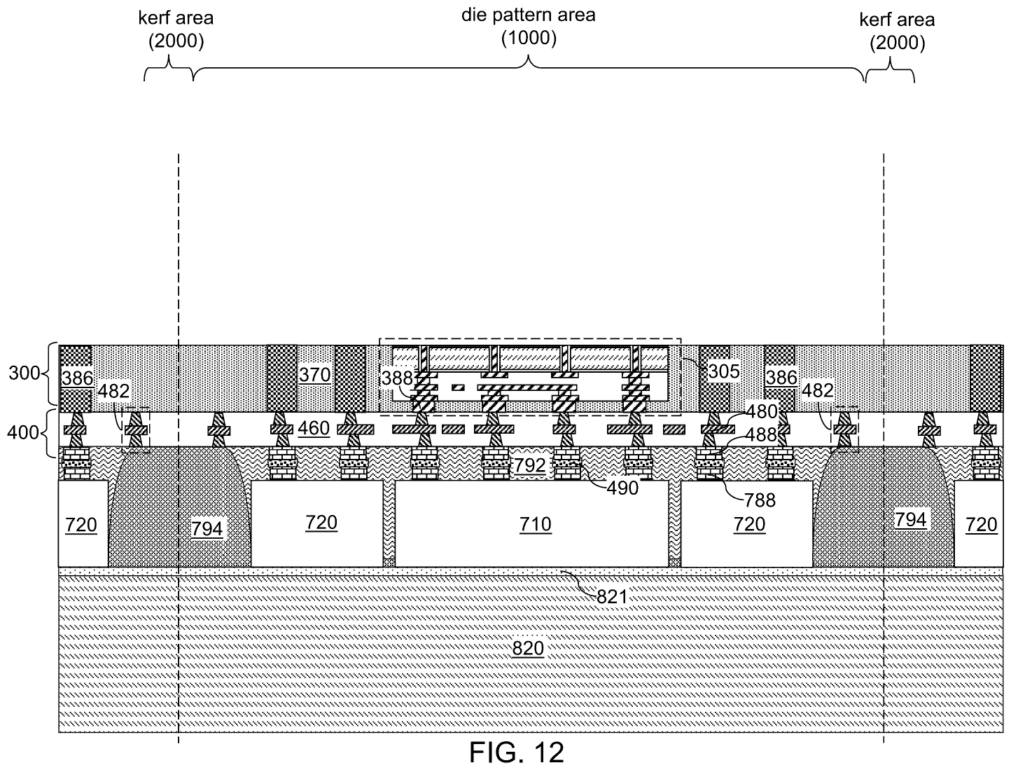

Referring to FIG. 12, the first carrier wafer 810 may be detached from the reconstituted wafer. In some embodiments, the first carrier wafer 810 may be removed by backside grinding. In embodiments in which the first carrier wafer 810 includes an optically transparent material and the first adhesive layer 811 comprises a light-to-heat conversion material, irradiation through the first carrier wafer 810 may be used to detach the first carrier wafer 810. In embodiments in which the first adhesive layer 811 comprises a thermally decomposable adhesive material, an anneal process or a laser irradiation may be used to detach the first carrier wafer 810. A suitable clean process may be performed to remove residual portions of the first adhesive layer 811.

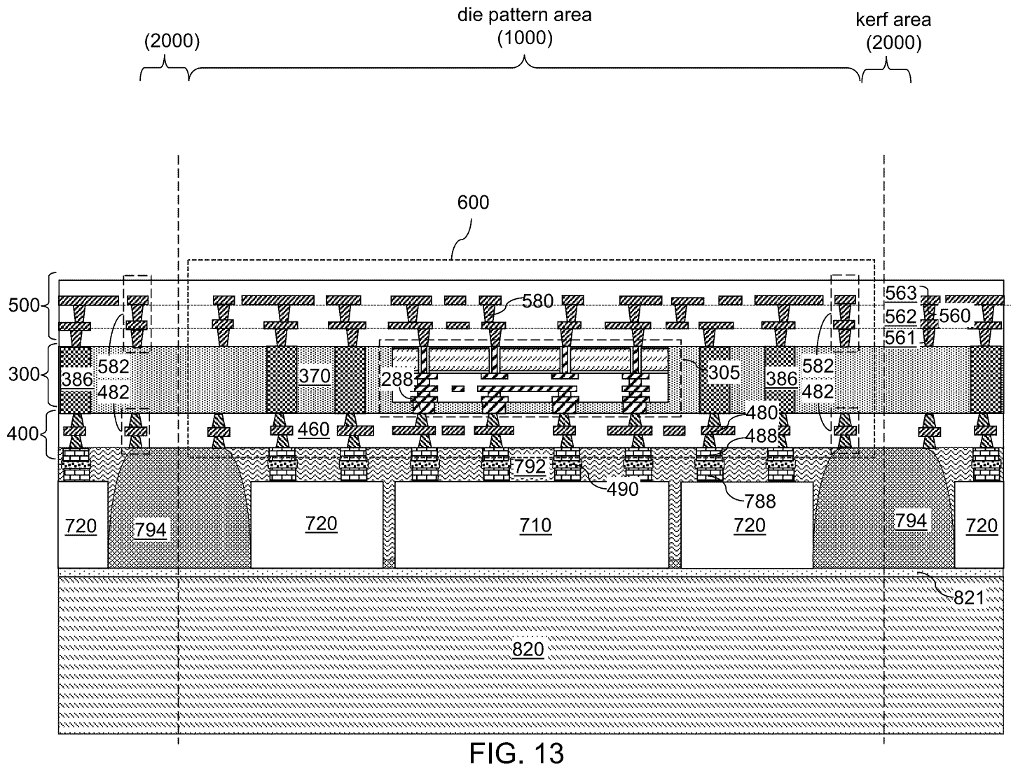

Referring to FIG. 13, distal redistribution dielectric layers 560 and distal redistribution wiring interconnects 580 may be formed over the interposer core layer 300. The distal redistribution dielectric layers 560 are also referred to as second redistribution dielectric layers, and the distal redistribution wiring interconnects 580 are also referred to as second redistribution wiring interconnects. A two-dimensional array of distal redistribution structures 500 may be formed over the interposer core layer 300. Each vertical stack of a portion of the interposer core layer 300 within a die pattern area 1000, an underlying proximal redistribution structure 400, and an overlying distal redistribution structure 500 constitutes an organic interposer die 600. A two-dimensional array of organic interposer dies 600 is formed.

According to various embodiments disclosed herein, each of the distal redistribution dielectric layers 560 comprises a respective distal dielectric negative photoresist material. As used herein, a “dielectric negative photoresist material” refers to a dielectric photo-sensitive compound that increases in polymerization and cross-linking density upon exposure to a designated light source, thereby becoming less soluble in a developer solution compared to its unexposed regions. Exemplary dielectric negative photoresist materials include, but are not limited to, polyimide and photosensitive epoxy-based polymer. According to an aspect of the present disclosure, the dielectric negative photoresist materials of the distal redistribution dielectric layers 560 are not irradiated with ultraviolet radiation for the purpose of patterning. Instead, patterned photoresist layers are formed above each distal redistribution dielectric layer 560, and an anisotropic etch process may be used to transfer the pattern in the patterned photoresist layer through a respective distal redistribution dielectric layer 560. The patterned photoresist layers are removed selective to underlying distal redistribution dielectric layers 560 using a respective ashing process, which uses process conditions that do not remove the distal redistribution dielectric layers 560.

Formation of the distal redistribution wiring interconnects 580 may be effected by depositing a metallic seed layer over a respective distal redistribution dielectric layer 560 including a respective set of via cavities therethrough, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 300 nm, and the copper seed layer may have a thickness in a range from 100 nm to 500 nm. The metallic fill material for the distal redistribution wiring interconnects 580 may include copper, nickel, or copper and nickel. The thickness of the metallic fill material that is deposited for each distal redistribution wiring interconnect 580 may be in a range from 1 microns to 4 microns, such as from 1 microns to 3 microns, although lesser or greater thicknesses may also be used. The total number of levels of wiring in each distal redistribution structure 500 (i.e., the levels of the distal redistribution wiring interconnects 580) may be in a range from 1 to 4.

According to an embodiment of the present disclosure, a subset of the distal redistribution wiring interconnects 580 may comprise edge seal ring structure 582. Each edge seal ring structure may comprise a contiguous vertical stack of at least one annular metal via structure and at least one annular metal line structure that forms a continuous wall structure that laterally encloses all other distal redistribution wiring interconnects 580 within a respective die pattern area 1000. Each die pattern area 1000 may be defined by the outermost periphery of an edge seal ring structure as seen in a plan view, such as a top-down view.

The distal redistribution dielectric layers 560 may comprise a first distal redistribution dielectric layer 561 having formed therein first distal redistribution wiring interconnects 580 and comprising a first dielectric negative photoresist material, and a terminal distal redistribution dielectric layer 563 overlying the first distal redistribution dielectric layer 561 having formed therein terminal distal redistribution wiring interconnects 580, and comprising a terminal dielectric negative photoresist material. In the illustrated example, the distal redistribution dielectric layers 560 comprises a first distal redistribution dielectric layer 561 having formed therein first distal redistribution wiring interconnects 580 and comprising a first dielectric negative photoresist material, a second distal redistribution dielectric layer 562 having second distal redistribution wiring interconnects 580 formed therein and comprising a second dielectric negative photoresist material, and a terminal distal redistribution dielectric layer 563 overlying the second distal redistribution dielectric layer 562, having formed therein terminal distal redistribution wiring interconnects 580, and comprising a terminal dielectric negative photoresist material. The dielectric negative photoresist materials within the distal redistribution dielectric layers 560 may be the same thereamongst, or may differ from one another.

Generally, the distal redistribution dielectric layers 560 and the distal redistribution wiring interconnects 580 may be formed over the interposer core layer 300. Each of the distal redistribution dielectric layers 560 comprises a respective dielectric negative photoresist material. The reconstituted wafer comprises an interposer core layer 300 comprising at least one of a two-dimensional array of bridge dies 305, and a two-dimensional array of sets of through-integrated-fan-out-via (TIV) structures 386.

Generally, a reconstituted wafer is formed, which comprises a two-dimensional array of organic interposer dies 600 that are interconnected to one another and a two-dimensional array of semiconductor die sets (710, 720). Each of the semiconductor die sets (710, 720) comprises at least one semiconductor die (710, 720) that is bonded to a respective one of the organic interposer dies 600. The two-dimensional array of organic interposer dies 600 comprises distal redistribution dielectric layers 560 that are composed of dielectric negative photoresist materials and having formed therein distal redistribution wiring interconnects 580. The two-dimensional array of organic interposer dies 600 are spaced from one another by regions of dicing channels (which are center regions of the kerf areas 2000) having a rectangular grid pattern. Each of the organic interposer dies 600 comprises a laterally-sealed area enclosed by a respective edge seal ring structure 582 and kerf areas 2000 laterally surrounding the laterally-sealed area (which is a die pattern area 1000).

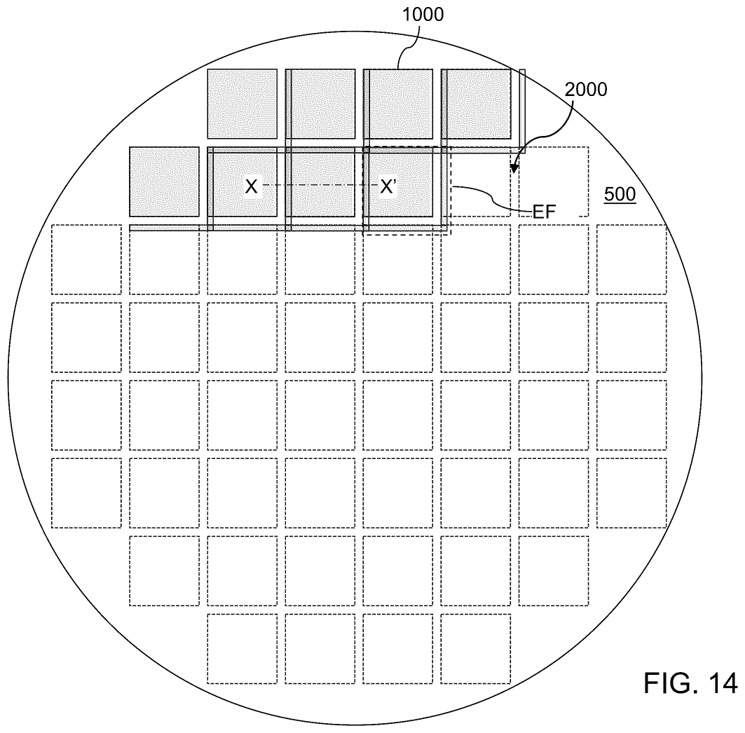

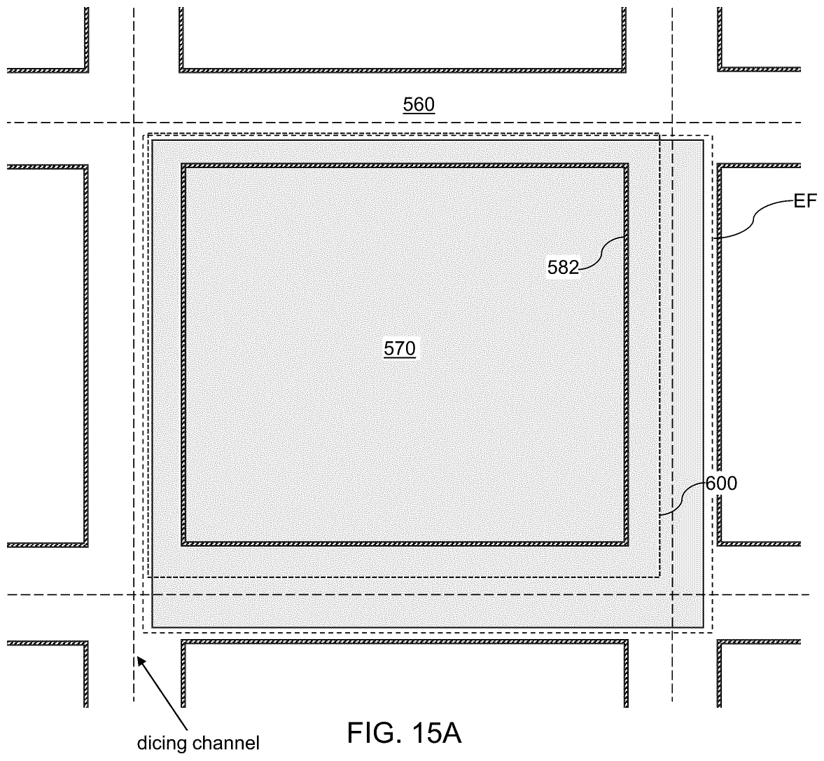

Referring to FIG. 14, a lithographic exposure process may be performed to lithographically exposure the distal redistribution dielectric layers 560 in the reconstituted wafer exposure field by exposure field EF. As used herein, an “exposure field” refers to the area on a semiconductor wafer that is illuminated by a light source during a single exposure event in the photolithography process. Each exposure field corresponds to the projection area of the image of the periphery of a photomask on the semiconductor wafer. The exposure field has the same periodicity as the two-dimensional array of die pattern areas 1000 on the reconstituted wafer. As discussed above, each of the distal redistribution dielectric layers 560 comprises a respective dielectric negative photoresist material, and the lithographic exposure process lithographically exposes each dielectric negative photoresist material within the distal redistribution dielectric layers 560.

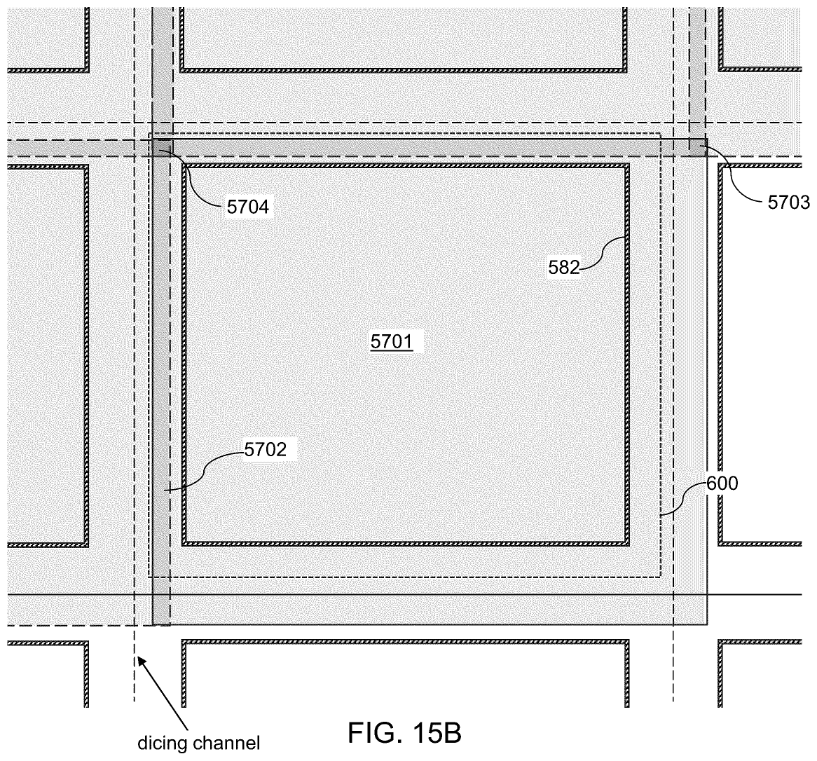

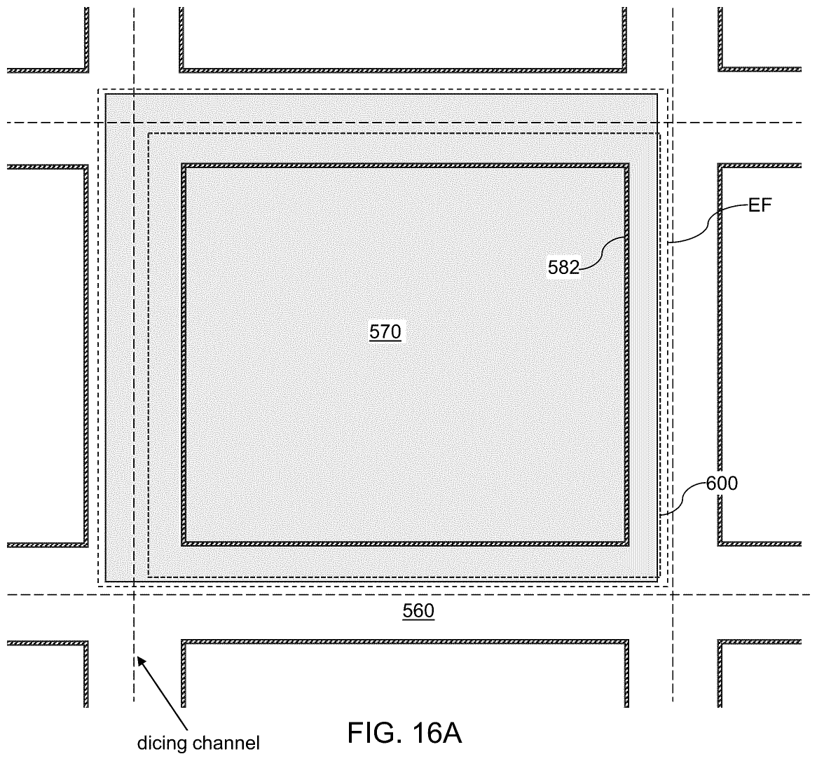

FIGS. 15A, 16A, 17A, 18A, 19A, and 20A illustrate the lithographic illumination area within an exposure field EF relative to the selected organic interposer die 600 for a single exposure for various lithographic exposure patterns according to embodiments of the present disclosure. Specifically, FIGS. 15A, 16A, 17A, 18A, 19A, and 20A illustrate patterns for the illuminated area (i.e., lithographic illumination area) that would be generated if only a single lithographic exposure were to be used for the first configuration, the second, configuration, the third configuration, the fourth configuration, the fifth configuration, and the sixth configuration, respectively, of the lithographic exposure patterns of the present disclosure.

FIGS. 15B, 16B, 17B, 18B, 19B, and 20B illustrate accumulated lithographic exposure patterns in the middle of the lithographic exposure process after completing lithographic exposure of one row of exposure fields EF and a subset of the exposure fields EF in a neighboring row. Thus, the patterns illustrated in FIGS. 15B, 16B, 17B, 18B, 19B, and 20B correspond to lithographic exposure patterns that are present on the reconstituted wafer at the processing step of FIG. 14. Single-exposed area 5701, double-exposed areas 5702, triple-exposed area 5703, and quadruple-exposed areas 5704 are illustrated. As used herein, a “single-exposed area” refers to an area in which illumination during lithographic exposure has been performed only once, a “double-exposed area” refers to an area in which illumination during lithographic exposure has been performed twice, a “triple-exposed area” refers to an area in which illumination during lithographic exposure has been performed three times, and a “quadruple-exposed area” refers to an area in which illumination during lithographic exposure has been performed four times, etc. FIGS. 15B, 16B, 17B, 18B, 19B, and 20B illustrate patterns for the cumulatively illuminated areas (i.e., lithographic illumination areas) for the first configuration, the second, configuration, the third configuration, the fourth configuration, the fifth configuration, and the sixth configuration, respectively, of the lithographic exposure patterns of the present disclosure.

Referring collectively to FIGS. 14-20B, the lithographic exposure process sequentially lithographically exposes areas of the dielectric negative photoresist materials using a two-dimensional array of exposure fields EF. Each exposure field EF within the two-dimensional array of exposure fields EF includes an illumination area that contains an entirety of a laterally-sealed area enclosed by a respective edge seal ring structure 582 located within a respective organic interposer die 600 and formed within the distal redistribution dielectric layers 560. Each exposure field EF within the two-dimensional array of exposure fields EF further includes a respective adjacent kerf area 2000 such that a double-exposed area 5702 is formed between each neighboring pair of organic interposer dies 600 within the two-dimensional array of organic interposer dies 600 upon completion of lithographic exposure of the dielectric negative photoresist materials.

Referring to FIGS. 15A and 15B, a first lithographic exposure pattern according to an embodiment of the present disclosure is illustrated. FIG. 15A is a schematic top-down view of a region around a selected organic interposer die 600 that illustrates the lithographic illumination area within an exposure field EF relative to the selected organic interposer die 600 in embodiments in which the first lithographic exposure pattern is used in each lithographic exposure according to an embodiment of the present disclosure. FIG. 15B is a schematic top-down view of a region around a selective organic interposer die 600 after sequentially lithographically exposing a subset of the organic interposer dies 600 up to the selected organic interposer die 600 in embodiments in which the first lithographic exposure pattern is used in each lithographic exposure according to an embodiment of the present disclosure.

Dicing channels are present between neighboring pairs of the organic interposer dies 600 within center regions of the kerf areas 2000 that are located between neighboring pairs of the edge seal ring structures 582. In the first lithographic exposure pattern, a lithographic illumination area 570 may be the same as an exposure field EF. The lithographic illumination area 570 may include an entire die pattern area 1000 (which is defined by an outer boundary of an edge seal ring structure 582) and may further include a first kerf area that is more proximal to a first additional die pattern area 1000 located within a same row and not yet lithographically exposed, a second kerf area that is more proximal to a second additional die pattern area 1000 located within a same column and not yet lithographically exposed, and a third kerf area that is more proximal to a third additional die pattern area 1000 located within an adjacent row and within an adjacent column and not yet lithographically exposed.

A double-exposed area 5702 is formed between each neighboring pair of organic interposer dies 600 in a respective one of the kerf areas 2000 within the two-dimensional array of organic interposer dies 600 upon completion of lithographic exposure of the dielectric negative photoresist materials. In embodiments in which the first lithographic exposure pattern is used, lithographic exposure of an exposure field EF that includes an entire area within an edge seal ring structure 582 of a selected organic interposer die 600 forms the double-exposed areas 5702 within an area of the selected organic interposer die 600. Each organic interposer die 600 that is laterally surrounded by four immediately neighboring organic interposer dies 600 is laterally bounded by a set of four dicing channels. In one embodiment, a two-dimensional array of quadruple-exposed areas is formed in proximity to intersection locations of the rectangular grid pattern of the dicing channels within the kerf areas 2000 of the two-dimensional array of organic interposer dies 600. Upon completion of the lithographic exposure process (i.e., after lithographically exposing all organic interposer dies 600), each organic interposer die 600 that is located at the center of a 3×3 matrix of organic interposer dies 600 may comprise one single-exposed area 5701, four double-exposed areas 5702, and four quadruple-exposed areas 5704.

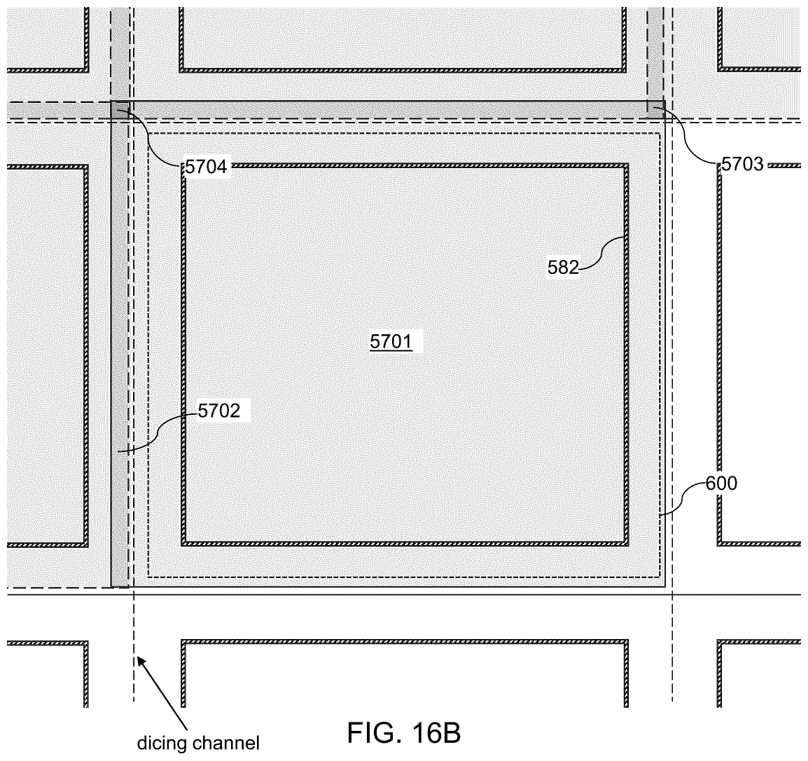

Referring to FIGS. 16A and 16B, a second lithographic exposure pattern according to an embodiment of the present disclosure is illustrated. FIG. 16A is a schematic top-down view of a region around a selected organic interposer die 600 that illustrates the lithographic illumination area within an exposure field EF relative to the selected organic interposer die 600 in embodiments in which the second lithographic exposure pattern is used in each lithographic exposure according to an embodiment of the present disclosure. FIG. 16B is a schematic top-down view of a region around a selective organic interposer die 600 after sequentially lithographically exposing a subset of the organic interposer dies 600 up to the selected organic interposer die 600 in embodiments in which the second lithographic exposure pattern is used in each lithographic exposure according to an embodiment of the present disclosure.

Dicing channels are present between neighboring pairs of the organic interposer dies 600 within center regions of the kerf areas 2000 that are located between neighboring pairs of the edge seal ring structures 582. In the second lithographic exposure pattern, a lithographic illumination area 570 may be the same as an exposure field EF. The lithographic illumination area 570 may include an entire die pattern area 1000 (which is defined by an outer boundary of an edge seal ring structure 582) and may further include a first kerf area that is more proximal to a first additional die pattern area 1000 located within a same row and previously lithographically exposed (thereby forming a double-exposed area 5702), a second kerf area that is more proximal to a second additional die pattern area 1000 located within a same column and previously lithographically exposed (and thus, forming another double-exposed area 5702), and a third kerf area that is more proximal to a third additional die pattern area 1000 located within an adjacent row and within an adjacent column and previously lithographically exposed (and thus, forming a quadruple-exposed area 5704).

A double-exposed area 5702 is formed between each neighboring pair of organic interposer dies 600 in a respective one of the kerf areas 2000 within the two-dimensional array of organic interposer dies 600 upon completion of lithographic exposure of the dielectric negative photoresist materials. In embodiments in which the second lithographic exposure pattern is used, lithographic exposure of an exposure field EF that includes an entire area within an edge seal ring structure 582 of a selected organic interposer die 600 forms the double-exposed areas 5702 within an area of a neighboring organic interposer die 600 (which has been previously exposed) that is laterally offset from the selected organic interposer die 600 by a respective one of the dicing channels. Each organic interposer die 600 that is laterally surrounded by four immediately neighboring organic interposer dies 600 is laterally bounded by a set of four dicing channels. In one embodiment, a two-dimensional array of quadruple-exposed areas is formed in proximity to intersection locations of the rectangular grid pattern of the dicing channels within the kerf areas 2000 of the two-dimensional array of organic interposer dies 600. Upon completion of the lithographic exposure process (i.e., after lithographically exposing all organic interposer dies 600), each organic interposer die 600 that is located at the center of a 3×3 matrix of organic interposer dies 600 may comprise one single-exposed area 5701, four double-exposed areas 5702, and four quadruple-exposed areas 5704.

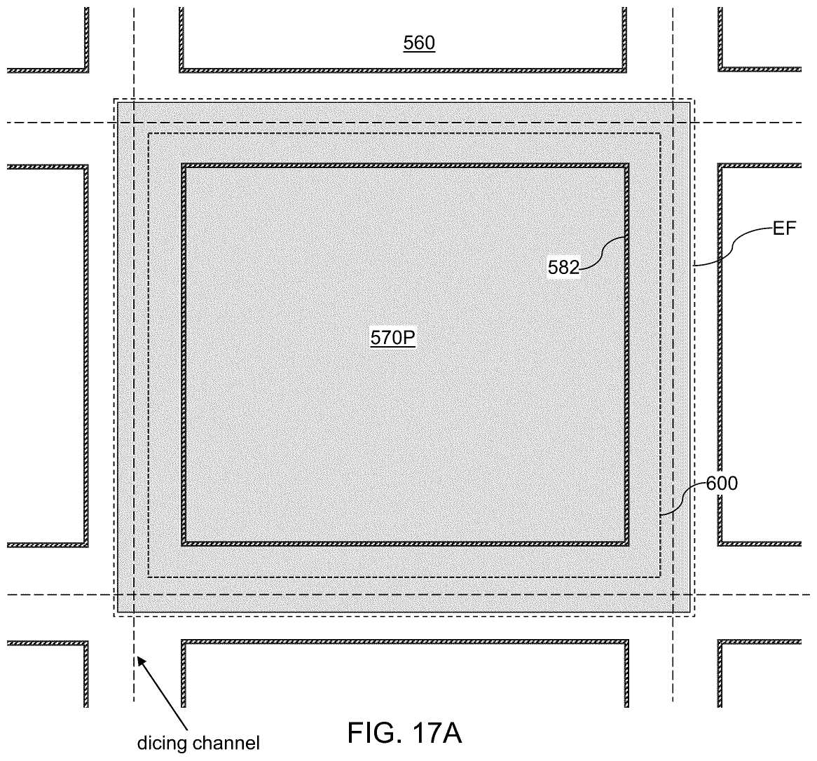

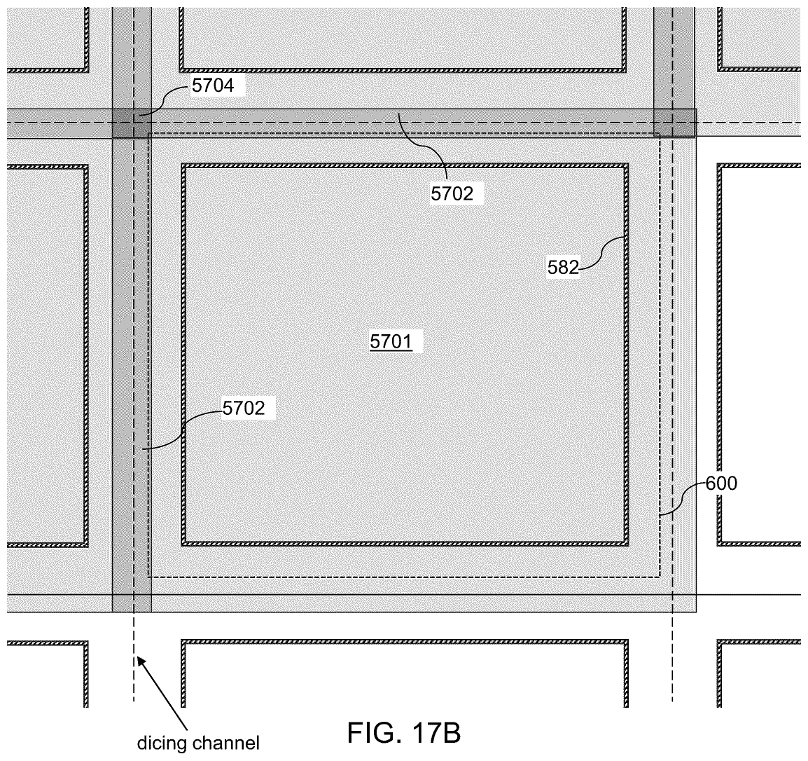

Referring to FIGS. 17A and 17B, a third lithographic exposure pattern according to an embodiment of the present disclosure is illustrated. FIG. 17A is a schematic top-down view of a region around a selected organic interposer die 600 that illustrates the lithographic illumination area within an exposure field EF relative to the selected organic interposer die 600 in embodiments in which the third lithographic exposure pattern is used in each lithographic exposure according to an embodiment of the present disclosure. FIG. 17B is a schematic top-down view of a region around a selective organic interposer die 600 after sequentially lithographically exposing a subset of the organic interposer dies 600 up to the selected organic interposer die 600 in embodiments in which the third lithographic exposure pattern is used in each lithographic exposure according to an embodiment of the present disclosure.

Dicing channels are present between neighboring pairs of the organic interposer dies 600 within center regions of the kerf areas 2000 that are located between neighboring pairs of the edge seal ring structures 582. In the third lithographic exposure pattern, a lithographic illumination area 570 may be the same as an exposure field EF. The lithographic illumination area 570 may include an entire die pattern area 1000 (which is defined by an outer boundary of an edge seal ring structure 582) and may further include all kerf area that are most proximal to the die pattern area 1000 and additional kerf areas that may be most proximal to any of the eight surrounding die pattern areas 1000 (or equivalents thereof in embodiments in which a peripheral die pattern area 1000 is lithographically exposed at a lithographic exposure step).

A double-exposed area 5702 is formed between each neighboring pair of organic interposer dies 600 in a respective one of the kerf areas 2000 within the two-dimensional array of organic interposer dies 600 upon completion of lithographic exposure of the dielectric negative photoresist materials. In embodiments in which the third lithographic exposure pattern is used, lithographic exposure of an exposure field EF that includes an entire area within an edge seal ring structure 582 of a selected organic interposer die 600 forms the double-exposed areas 5702 within the area of an organic interposer die 600 that includes the selected die pattern area 1000 and additionally within the areas of neighboring previously-exposed organic interposer dies 600. Each organic interposer die 600 that is laterally surrounded by four immediately neighboring organic interposer dies 600 is laterally bounded by a set of four dicing channels. In one embodiment, a two-dimensional array of quadruple-exposed areas is formed in proximity to intersection locations of the rectangular grid pattern of the dicing channels within the kerf areas 2000 of the two-dimensional array of organic interposer dies 600. Upon completion of the lithographic exposure process (i.e., after lithographically exposing all organic interposer dies 600), each organic interposer die 600 that is located at the center of a 3×3 matrix of organic interposer dies 600 may comprise one single-exposed area 5701, four double-exposed areas 5702, and four quadruple-exposed areas 5704.

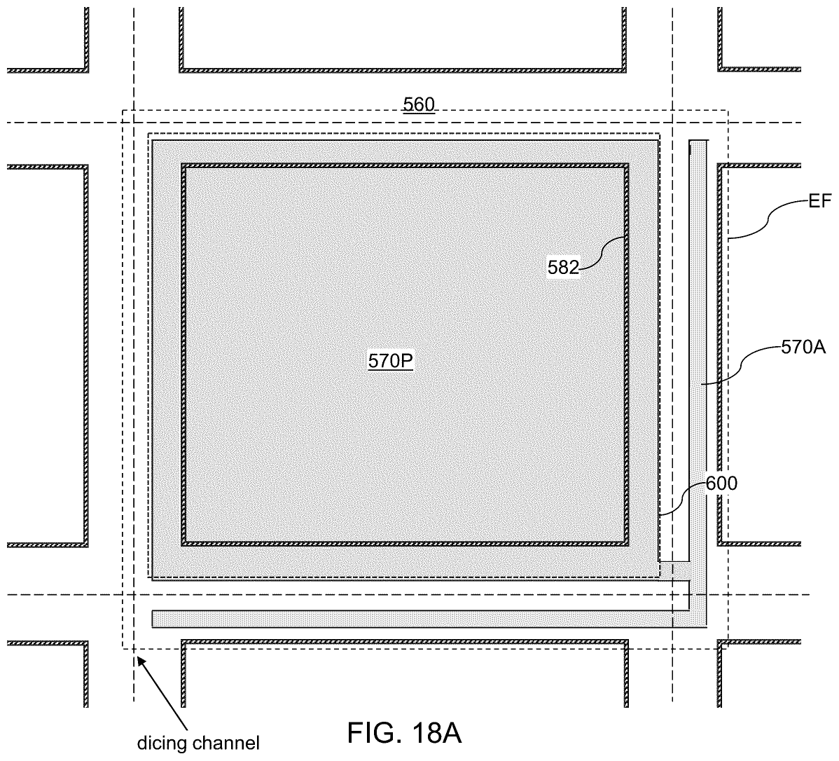

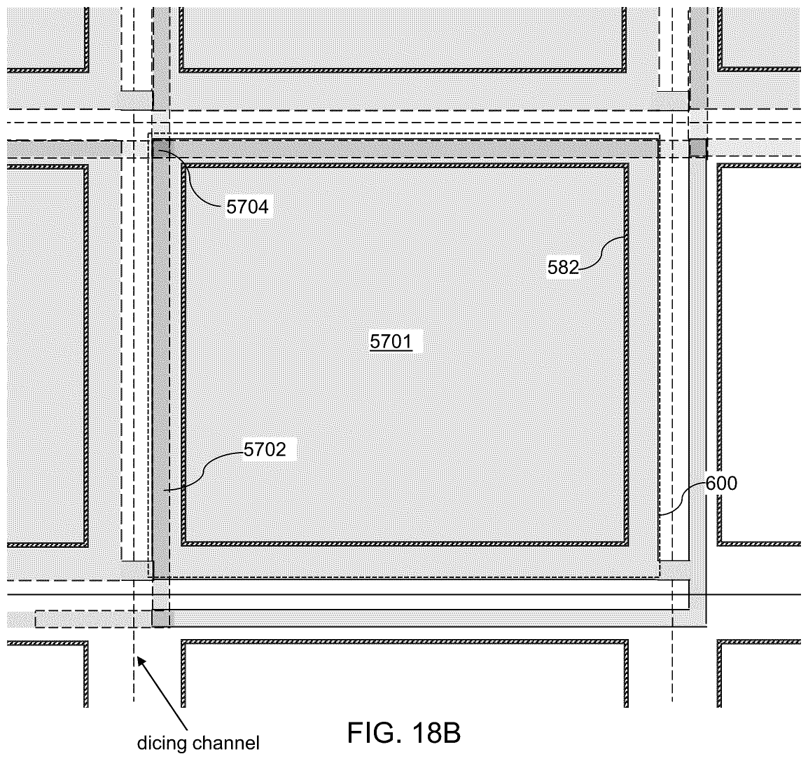

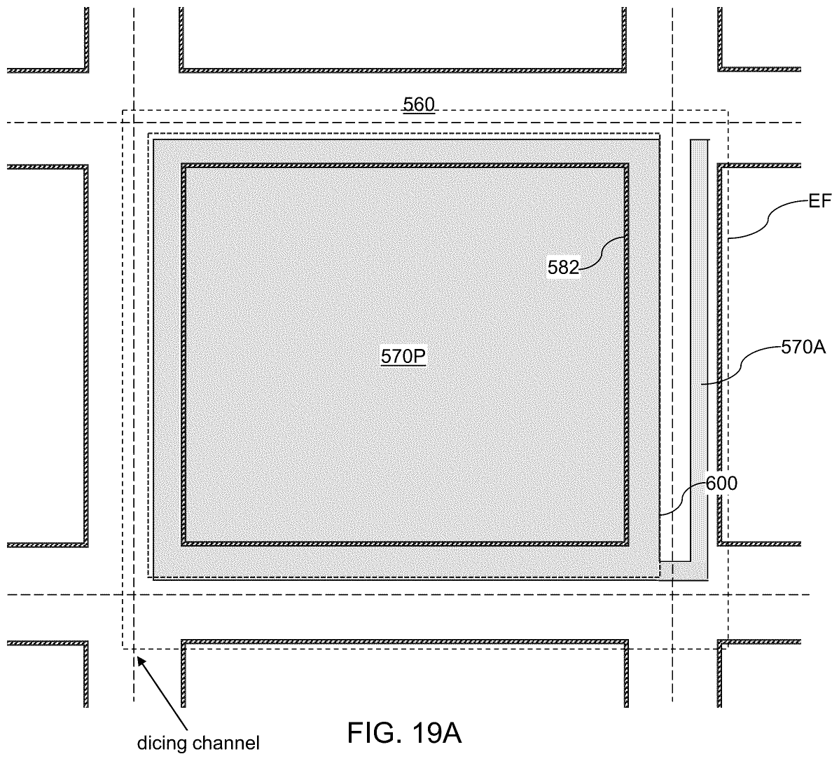

Referring to FIGS. 18A and 18B, a fourth lithographic exposure pattern according to an embodiment of the present disclosure is illustrated. FIG. 18A is a schematic top-down view of a region around a selected organic interposer die 600 that illustrates the lithographic illumination area within an exposure field EF relative to the selected organic interposer die 600 in embodiments in which a fourth lithographic exposure pattern is used in each lithographic exposure according to an embodiment of the present disclosure. FIG. 18B is a schematic top-down view of a region around a selective organic interposer die 600 after sequentially lithographically exposing a subset of the organic interposer dies 600 up to the selected organic interposer die 600 in embodiments in which the fourth lithographic exposure pattern is used in each lithographic exposure according to an embodiment of the present disclosure.

Dicing channels are present between neighboring pairs of the organic interposer dies 600 within center regions of the kerf areas 2000 that are located between neighboring pairs of the edge seal ring structures 582. In the fourth lithographic exposure pattern, a lithographic illumination area (570P, 570A) less than an exposure field EF. The areas of illumination within each exposure field EF includes a primary illumination area 570P, which includes at least the laterally-sealed area of a selected organic interposer die 600, i.e., the die pattern area 1000. In one embodiment, the primary illumination area 570P includes the entire die pattern area 1000 (which is defined by an outer boundary of an edge seal ring structure 582) and further includes kerf areas that are most proximal to the die pattern area 1000. The lithographic illumination area (570P, 570A) further includes an auxiliary illumination area 570A, which may be located at least within a neighboring organic interposer die 600 that is located adjacent to the selected organic interposer die 600. In one embodiment, the auxiliary illumination area 570A includes additional kerf areas that are most proximal to a respective neighboring die pattern area 1000 (or equivalents thereof if a peripheral die pattern area 1000 is lithographically exposed at a lithographic exposure step).

In one embodiment, at least one strip-shaped gap may be located between the primary illumination area 570P and the auxiliary illumination area 570A. Each strip-shaped gap is not illuminated during lithographic exposure of the selected organic interposer die 600. In one embodiment, the auxiliary illumination area 570A may comprise a first strip area that is most proximal to a neighboring die pattern area 1000 that belongs to the same row as the die pattern area 1000 within the primary illumination area 570P, and a second strip area that is most proximal to a neighboring die pattern area 1000 that belongs to the same column as the die pattern area 1000 within the primary illumination area 570P. In one embodiment, the first strip area and the second strip area may be interconnected to each other, and one of the first strip area and the second strip area may be connected to the primary illumination area 570P through a connection area. A first strip-shaped gap, i.e., a first unexposed area, may be present between the primary illumination area 570P and the first strip area. A second strip-shaped gap, i.e., a second unexposed area, may be present between the primary illumination area 570P and the second strip area. Each of the first strip-shaped gap and the second strip-shaped gap may have a respective rectangular shape.

Upon completion of the lithographic exposure of the dielectric negative photoresist materials of the distal redistribution dielectric layers 560, at least one of the dicing channels between neighboring pairs of exposure fields EF comprises a segment that is located between a respective neighboring pair of organic interposer dies 600 and is not lithographically exposed. In one embodiment, at least one of the dicing channels between neighboring pairs of exposure fields EF comprises an additional segment that is located between the respective neighboring pair of organic interposer dies 600 and is lithographically exposed upon completion of the lithographic exposure of the dielectric negative photoresist materials. In one embodiment, at least one of the dicing channels between neighboring pairs of exposure fields EF comprises an additional segment that is located between the respective neighboring pair of organic interposer dies 600 and is lithographically exposed upon completion of the lithographic exposure of the dielectric negative photoresist materials.

Generally, a lithographic exposure process may be performed, which sequentially lithographically exposes areas of the dielectric negative photoresist materials using a two-dimensional array of exposure fields EF such that each exposure field EF within the two-dimensional array of exposure fields EF includes an entirety of a laterally-sealed area enclosed by a respective edge seal ring structure 582 located within a respective organic interposer die 600 and formed within the distal redistribution dielectric layers 560. Upon completion of lithographic exposure of the dielectric negative photoresist materials, at least one of the dicing channels between neighboring pairs of exposure fields EF comprises a first segment that is not lithographically exposed and a second segment that is lithographically exposed.

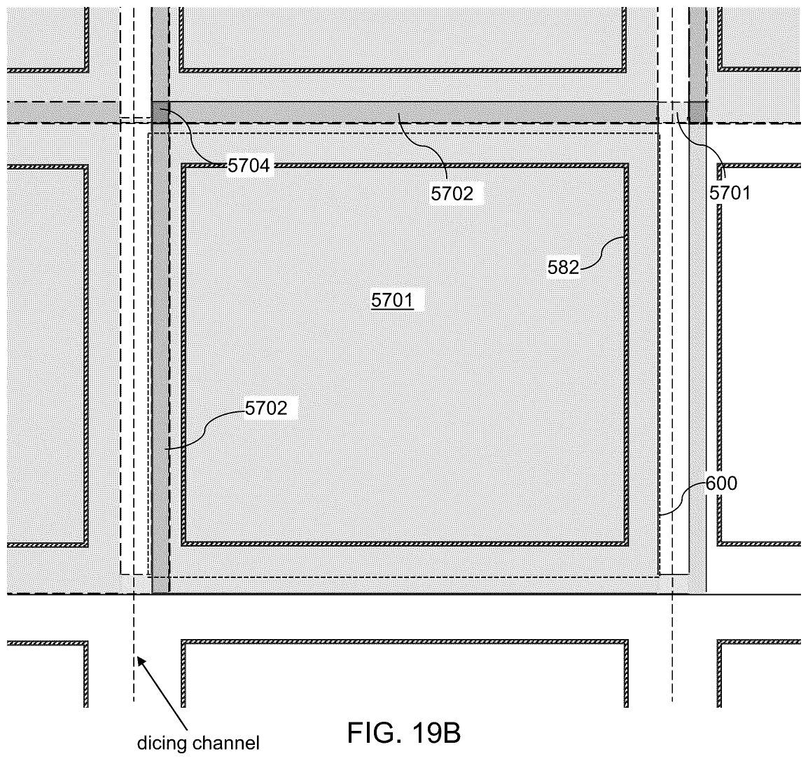

Referring to FIGS. 19A and 19B, a fifth lithographic exposure pattern according to an embodiment of the present disclosure is illustrated. FIG. 19A is a schematic top-down view of a region around a selected organic interposer die 600 that illustrates the lithographic illumination area within an exposure field EF relative to the selected organic interposer die 600 in embodiments in which a fifth lithographic exposure pattern is used in each lithographic exposure according to an embodiment of the present disclosure. FIG. 19B is a schematic top-down view of a region around a selective organic interposer die 600 after sequentially lithographically exposing a subset of the organic interposer dies 600 up to the selected organic interposer die 600 in embodiments in which the fifth lithographic exposure pattern is used in each lithographic exposure according to an embodiment of the present disclosure.

Dicing channels are present between neighboring pairs of the organic interposer dies 600 within center regions of the kerf areas 2000 that are located between neighboring pairs of the edge seal ring structures 582. In the fifth lithographic exposure pattern, a lithographic illumination area (570P, 570A) less than an exposure field EF. The areas of illumination within each exposure field EF includes a primary illumination area 570P, which includes at least the laterally-sealed area of a selected organic interposer die 600, i.e., the die pattern area 1000. In one embodiment, the primary illumination area 570P includes the entire die pattern area 1000 (which is defined by an outer boundary of an edge seal ring structure 582) and further includes kerf areas that are most proximal to the die pattern area 1000. The lithographic illumination area (570P, 570A) further includes an auxiliary illumination area 570A, which may be located at least within a neighboring organic interposer die 600 that is located adjacent to the selected organic interposer die 600. In one embodiment, the auxiliary illumination area 570A includes additional kerf areas that are most proximal to a respective neighboring die pattern area 1000 (or equivalents thereof if a peripheral die pattern area 1000 is lithographically exposed at a lithographic exposure step).

In one embodiment, a strip-shaped gap may be located between the primary illumination area 570P and the auxiliary illumination area 570A. The strip-shaped gap is not illuminated during lithographic exposure of the selected organic interposer die 600. In one embodiment, the auxiliary illumination area 570A may comprise a strip area that is most proximal to a neighboring die pattern area 1000 that belongs to the same row or to the same column as the die pattern area 1000 within the primary illumination area 570P. A strip-shaped gap, i.e., an unexposed area, may be present between the primary illumination area 570P and the strip area. The strip-shaped gap may have a rectangular shape.

Upon completion of the lithographic exposure of the dielectric negative photoresist materials of the distal redistribution dielectric layers 560, at least one of the dicing channels between neighboring pairs of exposure fields EF comprises a segment that is located between a respective neighboring pair of organic interposer dies 600 and is not lithographically exposed. In one embodiment, at least one of the dicing channels between neighboring pairs of exposure fields EF comprises an additional segment that is located between the respective neighboring pair of organic interposer dies 600 and is lithographically exposed upon completion of the lithographic exposure of the dielectric negative photoresist materials. In one embodiment, at least one of the dicing channels between neighboring pairs of exposure fields EF comprises an additional segment that is located between the respective neighboring pair of organic interposer dies 600 and is lithographically exposed upon completion of the lithographic exposure of the dielectric negative photoresist materials.

Generally, a lithographic exposure process may be performed, which sequentially lithographically exposes areas of the dielectric negative photoresist materials using a two-dimensional array of exposure fields EF such that each exposure field EF within the two-dimensional array of exposure fields EF includes an entirety of a laterally-sealed area enclosed by a respective edge seal ring structure 582 located within a respective organic interposer die 600 and formed within the distal redistribution dielectric layers 560. Upon completion of lithographic exposure of the dielectric negative photoresist materials, at least one of the dicing channels between neighboring pairs of exposure fields EF comprises a first segment that is not lithographically exposed and a second segment that is lithographically exposed.

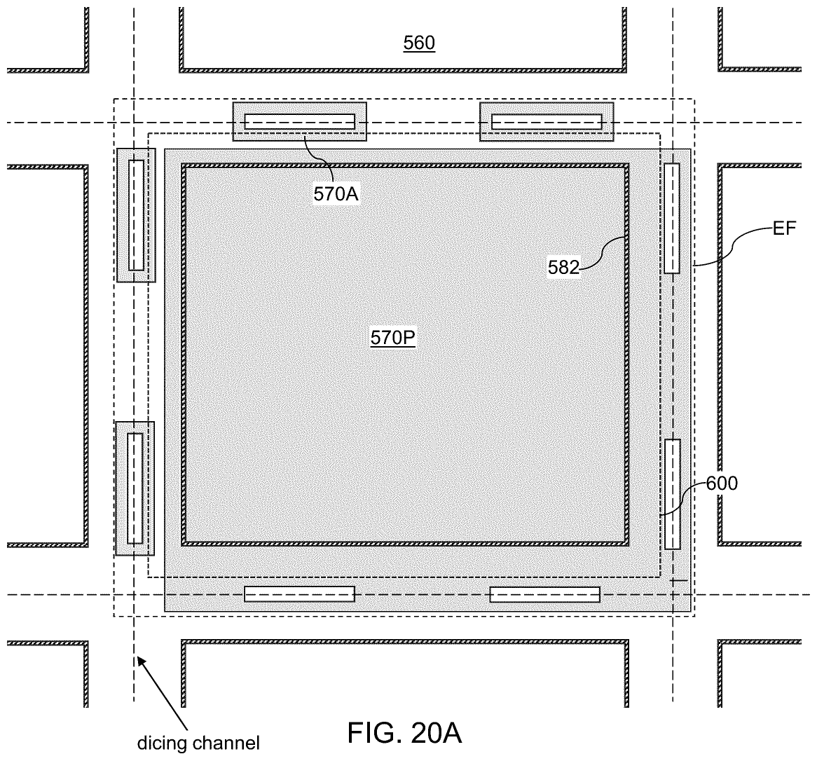

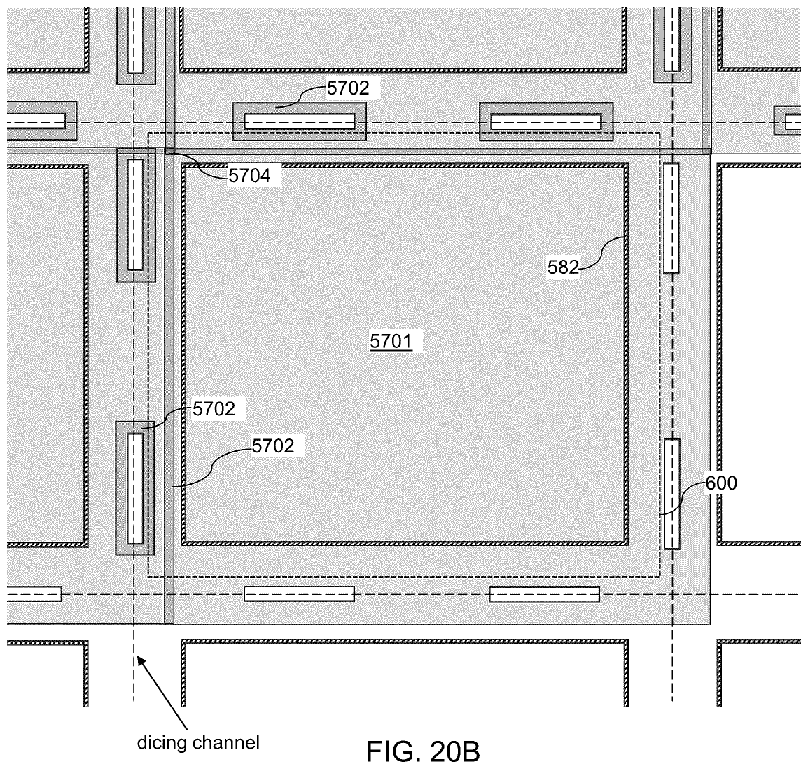

Referring to FIGS. 20A and 20B, a sixth lithographic exposure pattern according to an embodiment of the present disclosure is illustrated. FIG. 20A is a schematic top-down view of a region around a selected organic interposer die 600 that illustrates the lithographic illumination area within an exposure field EF relative to the selected organic interposer die 600 in embodiments in which a sixth lithographic exposure pattern is used in each lithographic exposure according to an embodiment of the present disclosure. FIG. 20B is a schematic top-down view of a region around a selective organic interposer die 600 after sequentially lithographically exposing a subset of the organic interposer dies 600 up to the selected organic interposer die 600 in embodiments in which the sixth lithographic exposure pattern is used in each lithographic exposure according to an embodiment of the present disclosure.

Dicing channels are present between neighboring pairs of the organic interposer dies 600 within center regions of the kerf areas 2000 that are located between neighboring pairs of the edge seal ring structures 582. In the sixth lithographic exposure pattern, a lithographic illumination area (570P, 570A) less than an exposure field EF. The areas of illumination within each exposure field EF includes a primary illumination area 570P, which includes at least the laterally-sealed area of a selected organic interposer die 600, i.e., the die pattern area 1000. In one embodiment, the primary illumination area 570P includes the entire die pattern area 1000 (which is defined by an outer boundary of an edge seal ring structure 582) and further includes kerf areas that are most proximal to the die pattern area 1000 with at least one opening that overlaps with a respective dicing channel. Each opening may have a rectangular shape. The width of each opening may be less than the width of a kerf area 2000 between neighboring pairs of die pattern areas 1000. The lithographic illumination area (570P, 570A) further includes at least one auxiliary illumination area 570A that is spaced from the primary illumination area 570P. In one embodiment, each auxiliary illumination area 570A may have a shape of a rectangular frame with a rectangular opening therein. In one embodiment, each rectangular opening within a respective rectangular frame may have an areal overlap with a respective dicing channel. In one embodiment, a plurality of auxiliary illumination area 570A may be provided within an exposure field EF.

In one embodiment, a strip-shaped gap may be located between the primary illumination area 570P and the auxiliary illumination area 570A. The strip-shaped gap is not illuminated during lithographic exposure of the selected organic interposer die 600. In one embodiment, the auxiliary illumination area 570A may comprise a strip area that is most proximal to a neighboring die pattern area 1000 that belongs to the same row or to the same column as the die pattern area 1000 within the primary illumination area 570P. A strip-shaped gap, i.e., an unexposed area, may be present between the primary illumination area 570P and the strip area. The strip-shaped gap may have a rectangular shape.

Upon completion of the lithographic exposure of the dielectric negative photoresist materials of the distal redistribution dielectric layers 560, at least one of the dicing channels between neighboring pairs of exposure fields EF comprises a segment that is located between a respective neighboring pair of organic interposer dies 600 and is not lithographically exposed. In one embodiment, at least one of the dicing channels between neighboring pairs of exposure fields EF comprises an additional segment that is located between the respective neighboring pair of organic interposer dies 600 and is lithographically exposed upon completion of the lithographic exposure of the dielectric negative photoresist materials. In one embodiment, at least one of the dicing channels between neighboring pairs of exposure fields EF comprises an additional segment that is located between the respective neighboring pair of organic interposer dies 600 and is lithographically exposed upon completion of the lithographic exposure of the dielectric negative photoresist materials.

Generally, a lithographic exposure process may be performed, which sequentially lithographically exposes areas of the dielectric negative photoresist materials using a two-dimensional array of exposure fields EF such that each exposure field EF within the two-dimensional array of exposure fields EF includes an entirety of a laterally-sealed area enclosed by a respective edge seal ring structure 582 located within a respective organic interposer die 600 and formed within the distal redistribution dielectric layers 560. Upon completion of lithographic exposure of the dielectric negative photoresist materials, at least one of the dicing channels between neighboring pairs of exposure fields EF comprises a first segment that is not lithographically exposed and a second segment that is lithographically exposed. In one embodiment, the first segment is laterally surrounded by a double-exposed area 5702 that is lithographically exposed twice during the lithographic exposure of the dielectric negative photoresist materials. In one embodiment, the areas of openings within the primary illumination area 570P in an exposure field EF may coincide with the areas of openings within the at least one auxiliary illumination area 570A in a neighboring exposure field EF.

Illumination of ultraviolet radiation on the dielectric negative photoresist materials of the distal redistribution dielectric layers 560 causes cross-linking of the molecules, i.e., polymerization, within the materials of the dielectric negative photoresist materials. According to an aspect of the present disclosure, the duration of each lithographic exposure is selected such that a single lithographic exposure of the dielectric negative photoresist materials do not cause complete cross-linking of the molecules of the materials of the dielectric negative photoresist materials. In this embodiment, double exposure of the materials of the dielectric negative photoresist materials causes additional cross-linking of the molecules, and quadruple exposure of the materials of the dielectric negative photoresist materials causes even more cross-linking of the molecules. In other words, the volume density of the cross-links in the polymerized molecules increases with additional lithographic illumination. Upon development of the materials of the distal redistribution dielectric layers 560 after completion of the lithographic exposure process, the different cross-link densities in single-exposed areas 5701, double-exposed areas 5702, and quadruple-exposed areas 5704 are manifested as differences in the height of the developed dielectric negative photoresist materials of the distal redistribution dielectric layers 560.

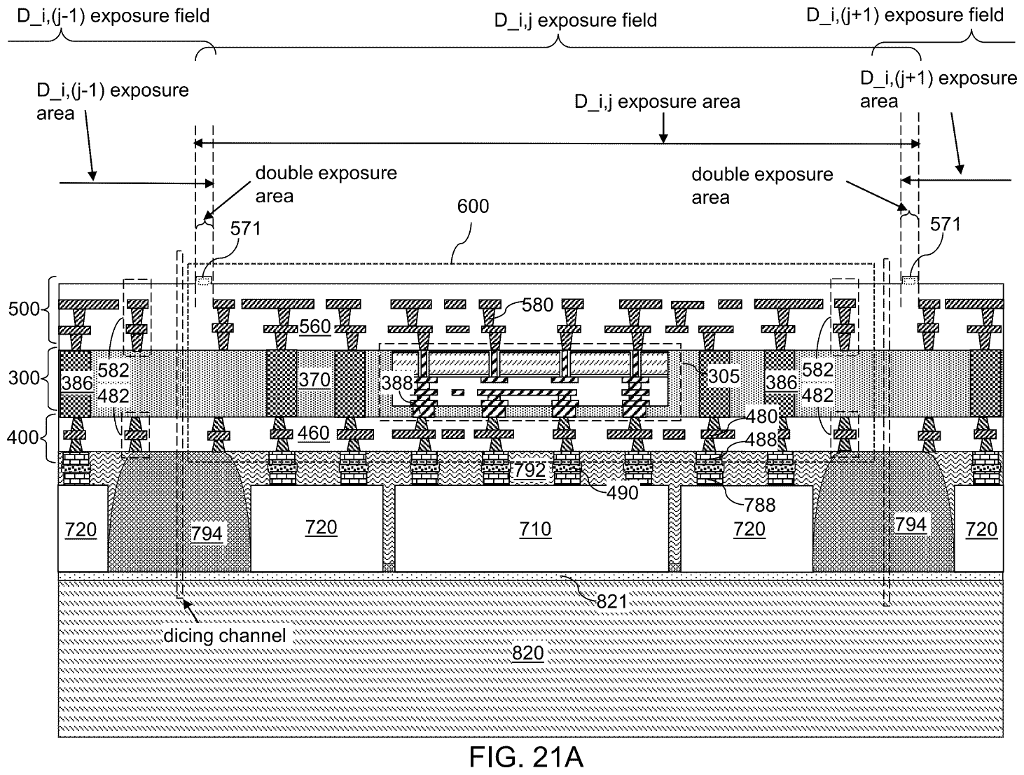

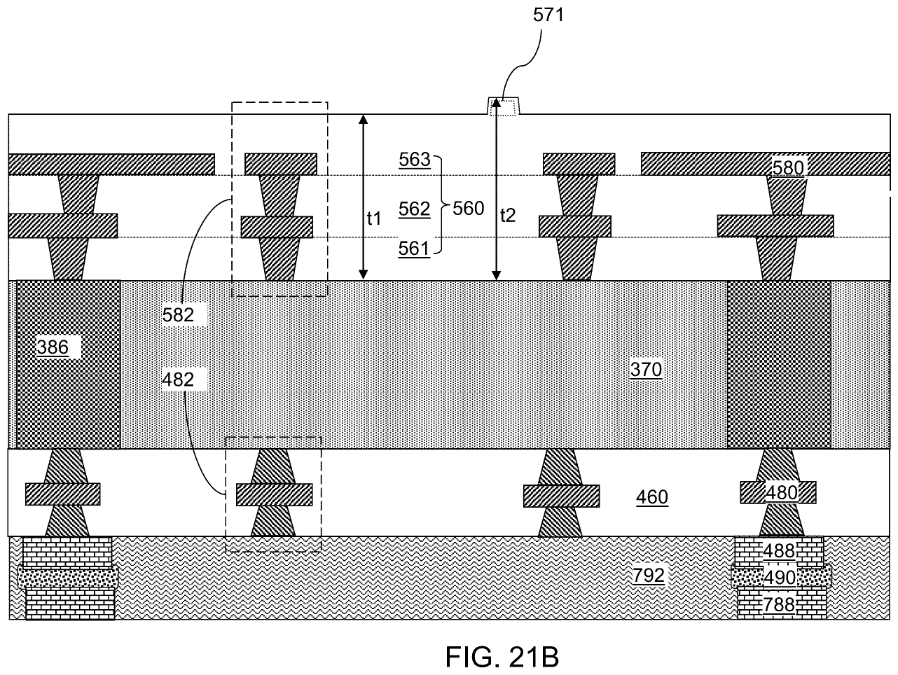

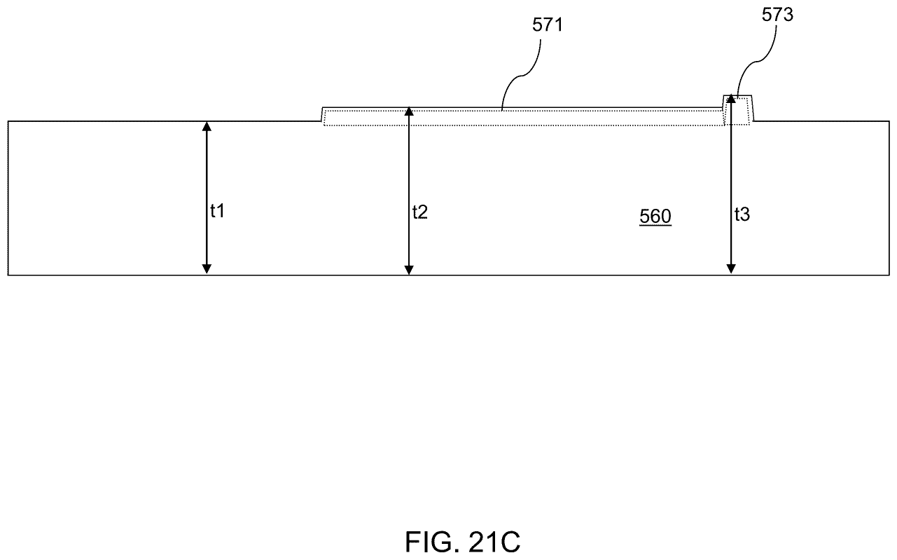

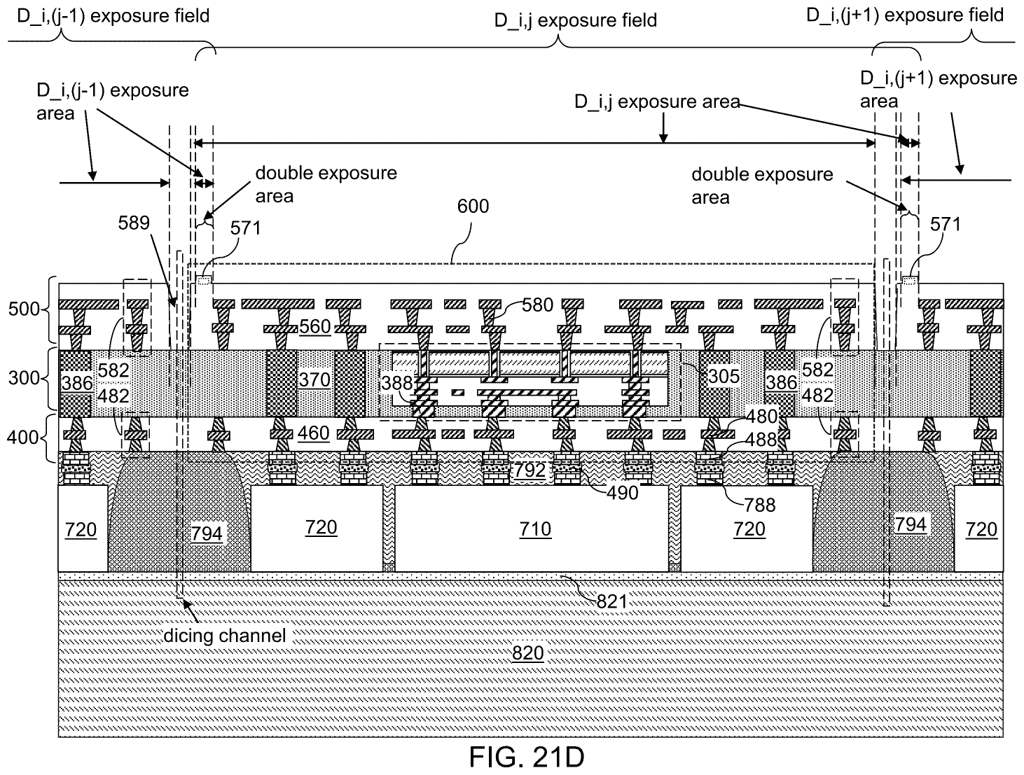

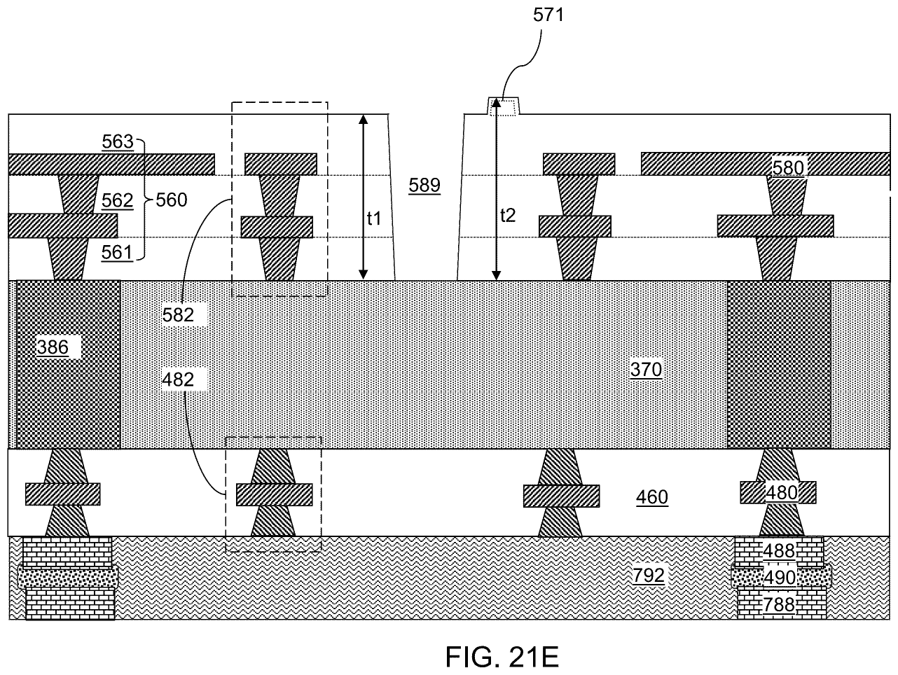

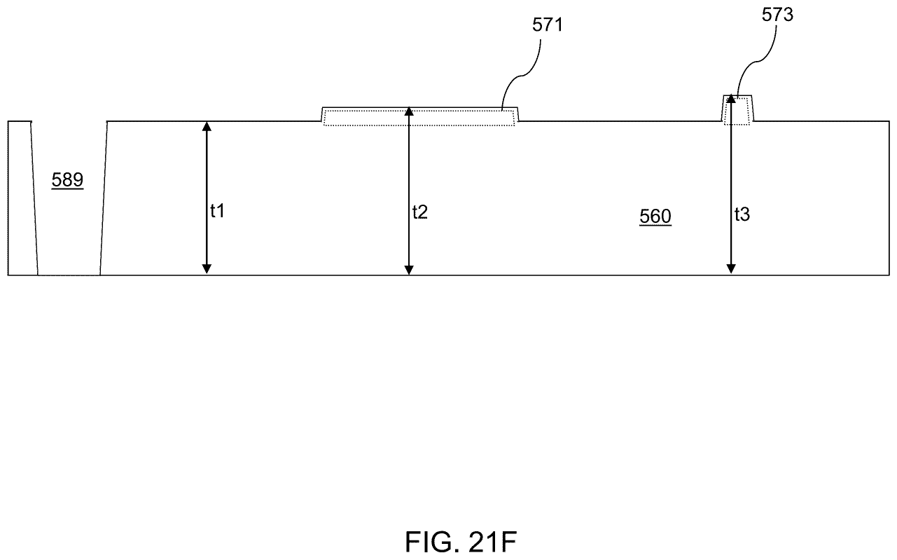

Referring to FIGS. 21A-21F, various views of the exemplary structure after development are shown. FIG. 21A is a vertical cross-sectional view of the exemplary structure after development of the distal redistribution dielectric layers 560 according to an embodiment of the present disclosure. FIG. 21B is a magnified view of a region of the vertical cross-sectional view of FIG. 21A. FIG. 21C is a schematic vertical cross-sectional view of a region of the distal redistribution dielectric layers 560 of FIG. 21A. FIG. 21D is an additional vertical cross-sectional view for some configurations of the exemplary structure after development of the distal redistribution dielectric layers 560 according to an embodiment of the present disclosure. FIG. 21E is a magnified view of a region of the vertical cross-sectional view of FIG. 21D. FIG. 21F is a schematic vertical cross-sectional view of a region of the distal redistribution dielectric layers 560 of FIG. 21D.

The views of FIGS. 21A-21C are common across all configurations of the exemplary structure as described with reference to FIGS. 15A-20B. The views of FIGS. 21D-21F may be generated from the fourth, fifth, and sixth configurations of the exemplary structure as described with reference to FIGS. 18A-20B, i.e., for configurations in which lithographically unilluminated areas are present in the distal redistribution dielectric layers 560, and thus, local trenches 589 are formed in the kerf areas 2000. The views of FIGS. 21A, 21B, 21D, and 21E are for a die D_i,j located in the i-th row and in the j-th column within a two-dimensional array of organic interposer dies 600. Overlap of exposure fields EF is illustrated among the exposure field EF for the die D_i,j located in the i-th row and in the j-th column, the exposure field EF for the die D_i, (j−1) located in the i-th row and in the (j−1)-th column, and the exposure field EF for the die D_i, (j+1) located in the i-th row and in the (j+1)-th column.

Generally, a double-exposed area 5702 is formed between each neighboring pair of organic interposer dies 600 in a respective one of the kerf areas 2000 within the two-dimensional array of organic interposer dies 600 upon completion of lithographic exposure of the dielectric negative photoresist materials. Upon development, each double-exposed area 5702 forms a region having a greater thickness than a region corresponding to a single-exposed area 5701. Further, a two-dimensional array of quadruple-exposed areas 5704 may be formed in proximity to intersection locations of the rectangular grid pattern of the dicing channels within the kerf areas 2000 of the two-dimensional array of organic interposer dies 600. Upon development, each quadruple-exposed area 5704 forms a region having a greater thickness than a region corresponding to a double-exposed area 5702.

Generally, the entirety of the distal redistribution dielectric layers 560 within each die pattern area 1000 (which is defined by the outer periphery of an edge seal ring structure 582) is single-exposed, and has a first thickness t1 after development. For each organic interposer die 600, the portion of the distal redistribution dielectric layers 560 located outside the die pattern area 1000 has a shape of a generally rectangular frame, and constitutes an enclosure wall portion that laterally surrounds the edge seal ring structure 582. The enclosure wall portion of the distal redistribution dielectric layers 560 comprises a first region (corresponding to the single-exposed areas 5701) having a first thickness t1, second regions (corresponding to the double-exposed areas 5702) having a second thickness t2 that is greater than the first thickness t1, and at least one third region (corresponding to a respective quadruple-exposed area 5704) having a third thickness t3 that is greater than the second thickness. Each of the second regions comprises a respective first uniform-height protrusion 571 having a first uniform width. Each of the third regions comprises a respective second uniform-height protrusion 573 having a second uniform width. In an illustrative example, the first thickness t1 may be in a range from 3 microns to 30 microns, the difference between the second thickness t2 and the first thickness t1 may be in a range from 0.3 microns to 3 microns, and the difference between the third thickness t3 and the second thickness t2 may be in a range from 0.15 microns to 3 microns.

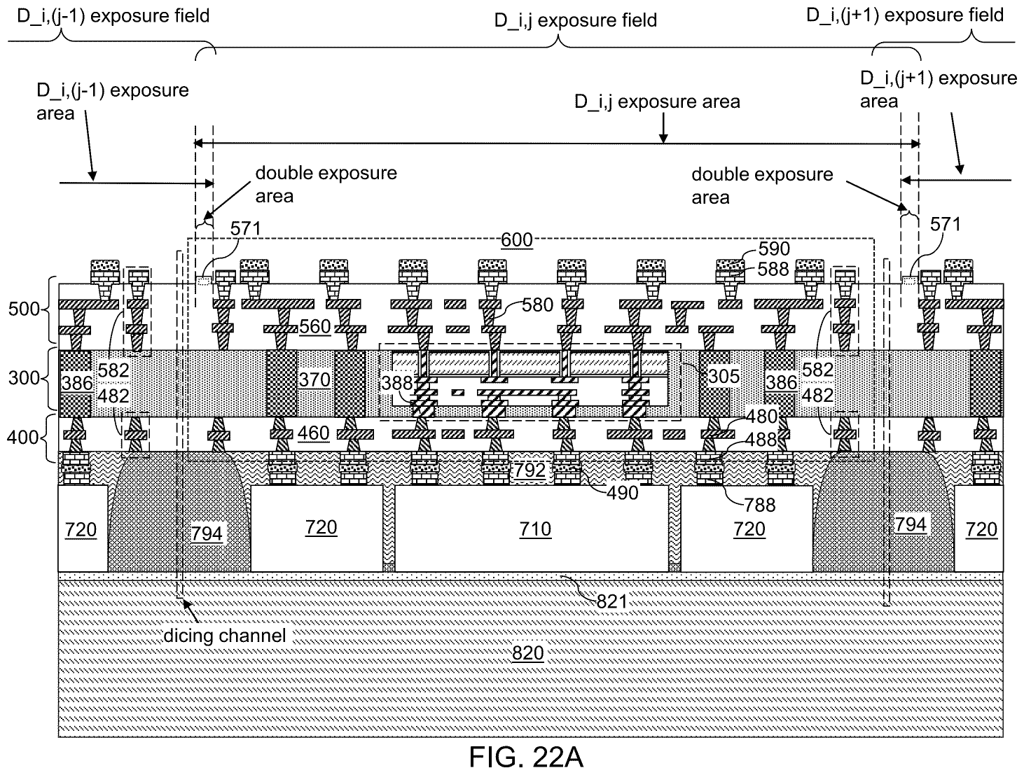

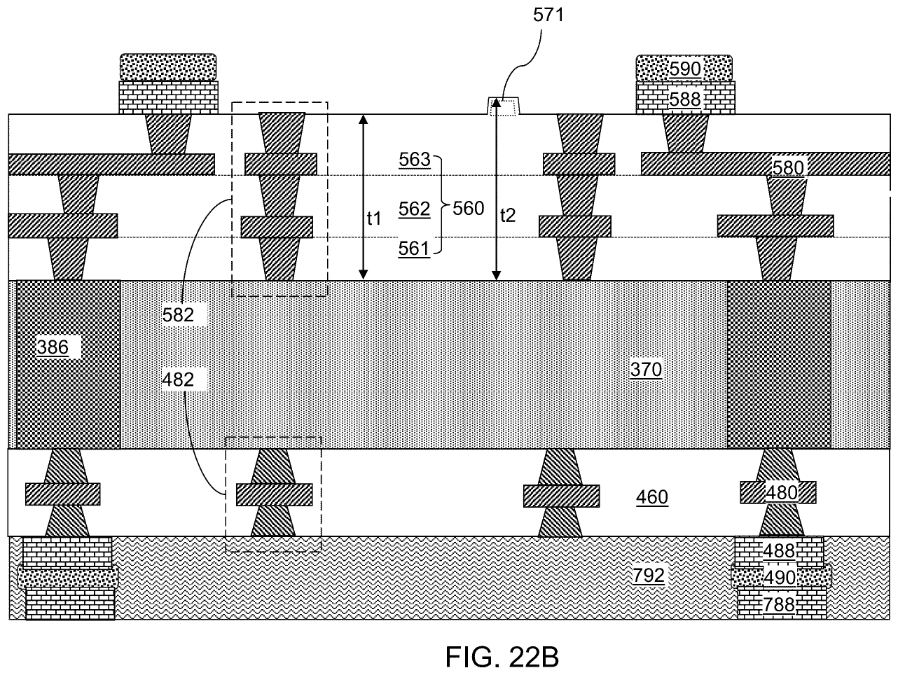

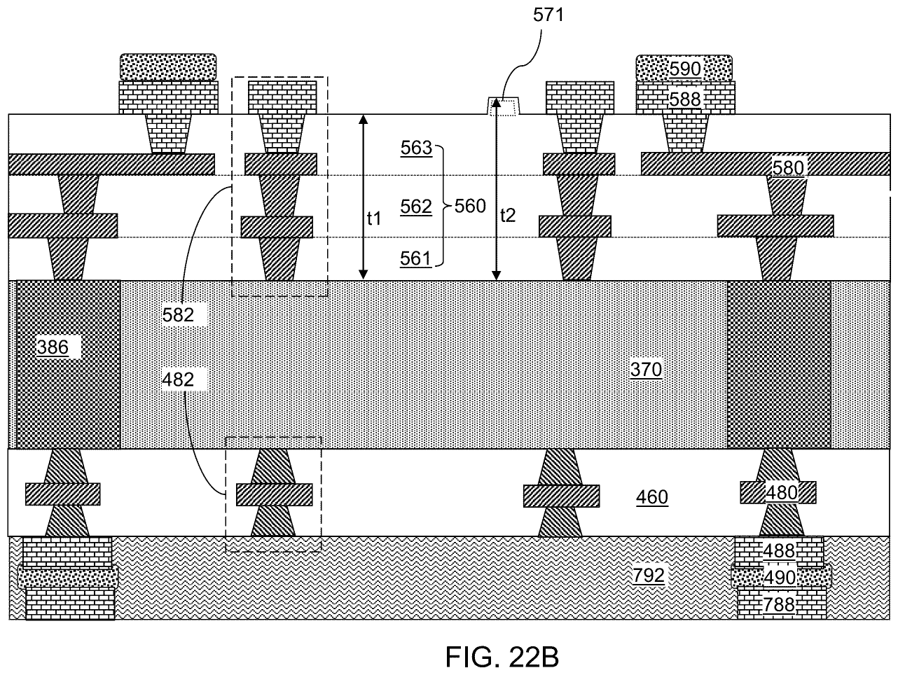

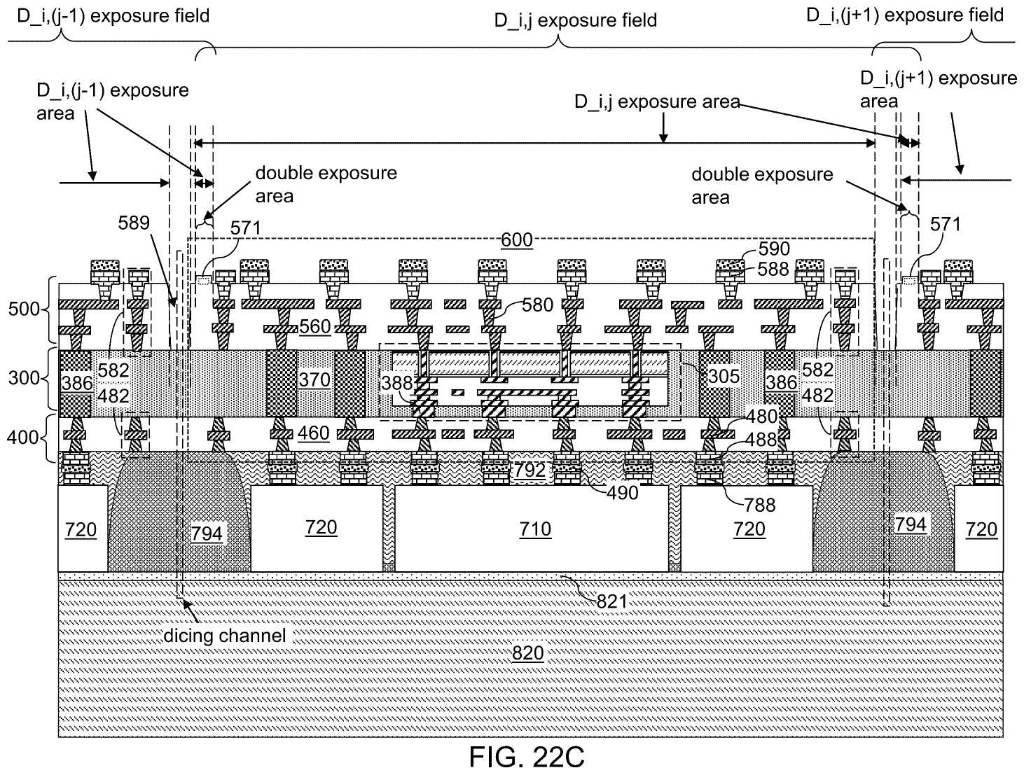

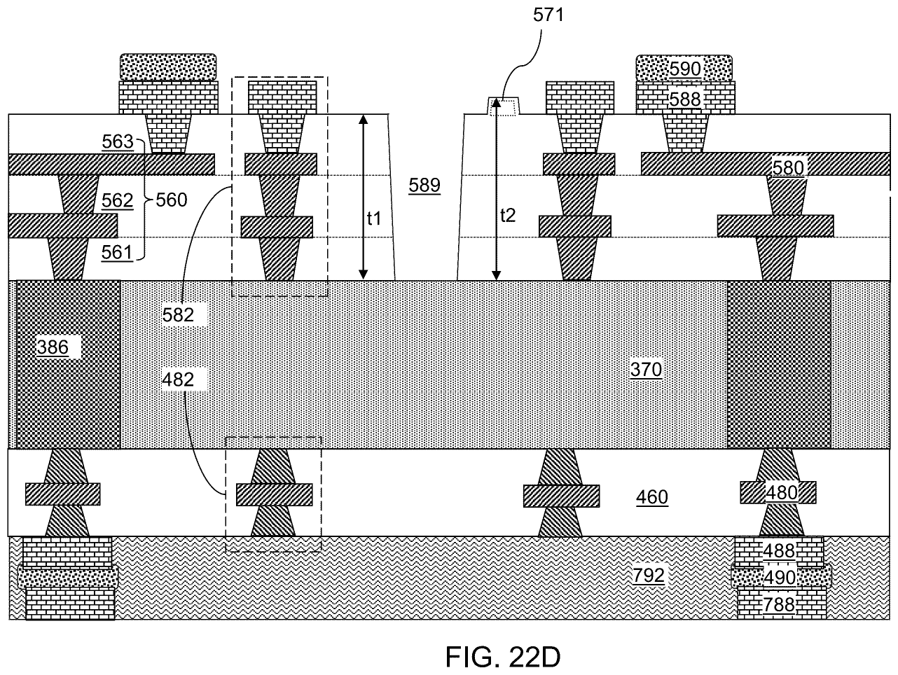

Referring to FIGS. 22A-22D, various views of the exemplary structure are shown after formation of distal bump structures 588 and solder material portions which are herein referred to as substrate-side solder material portions 590. FIG. 22A is a vertical cross-sectional view of a region of the exemplary structure after formation of distal bump structures 588 and substrate-side solder material portions 590 according to an embodiment of the present disclosure. FIG. 22B is a magnified view of a region of the vertical cross-sectional view of FIG. 22A. FIG. 22C is an additional vertical cross-sectional view for some configurations of the exemplary structure after formation of distal bump structures 588 and substrate-side solder material portions 590 according to an embodiment of the present disclosure. FIG. 22D is a magnified view of a region of the vertical cross-sectional view of FIG. 21C.

The views of FIGS. 22A and 22B are common across all configurations of the exemplary structure as described with reference to FIGS. 15A-20B. The views of FIGS. 22C and 22D may be generated from the fourth, fifth, and sixth configurations of the exemplary structure as described with reference to FIGS. 18A-20B, i.e., for configurations in which lithographically unilluminated areas are present in the distal redistribution dielectric layers 560, and thus, local trenches 589 are formed in the kerf areas 2000. Generally, the distal bump structures 588 are formed through the terminal distal redistribution dielectric layer on a respective one of the distal redistribution wiring interconnects 580. The distal bump structures 588 may be formed as C4 bonding pads or microbump structures for C2 bonding. A bump-level metallic ring may be added to each edge ring seal structure. The substrate-side solder material portions 590 may be formed on the distal bump structures 588.

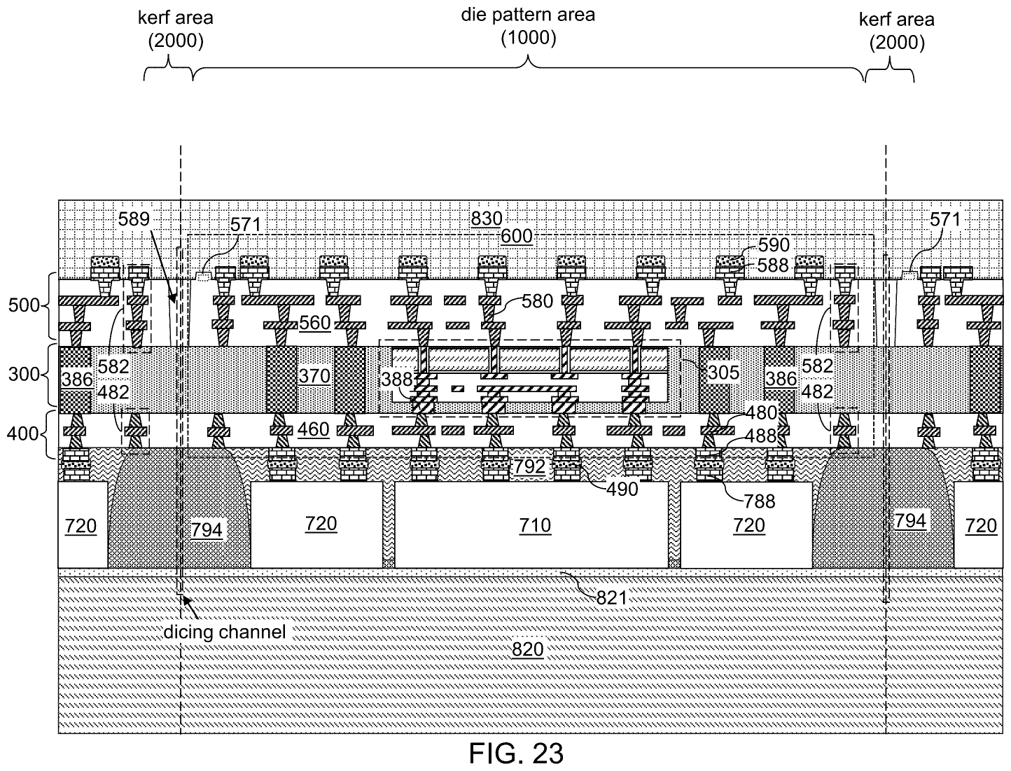

Referring to FIG. 23, a backside support tape 830 may be attached to the two-dimensional array of organic interposer dies 600 on the side of the two-dimensional array of distal redistribution structures 500.

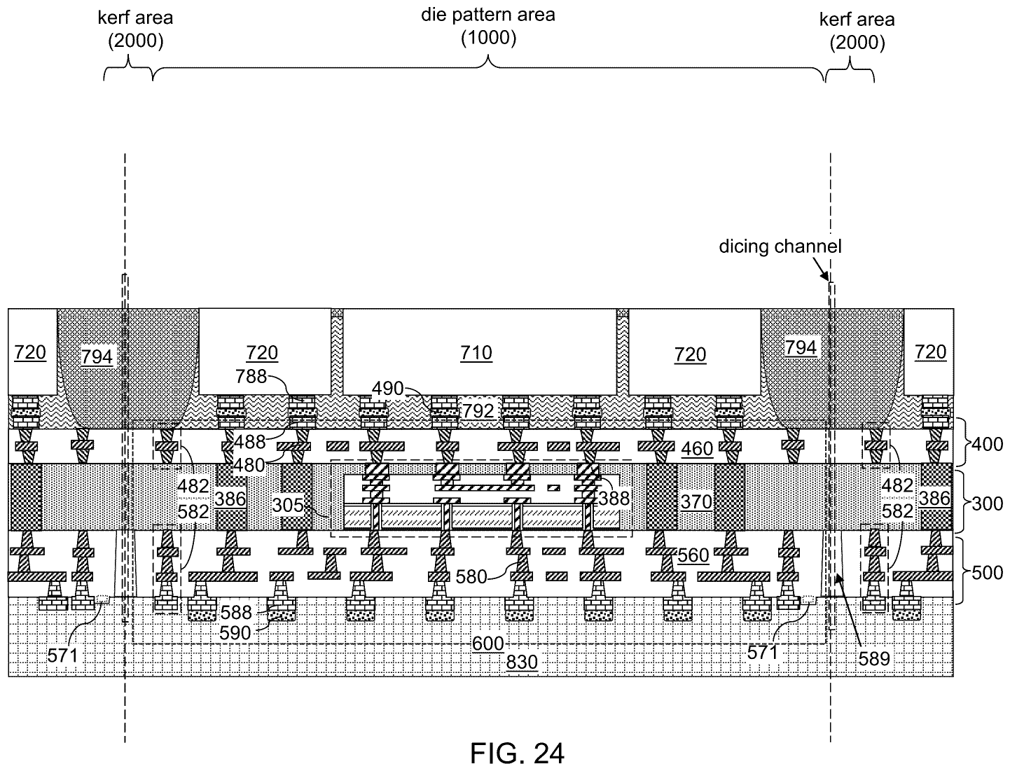

Referring to FIG. 24, the second carrier wafer 820 may be detached from the reconstituted wafer. In one embodiment, the second carrier wafer 820 includes an optically transparent material and the second adhesive layer 821 comprises a light-to-heat conversion material, irradiation through the second carrier wafer 820 may be used to detach the second carrier wafer 820. In embodiments in which the second adhesive layer 821 comprises a thermally decomposable adhesive material, an anneal process or a laser irradiation may be used to detach the second carrier wafer 820. A suitable clean process may be performed to remove residual portions of the second adhesive layer 821.

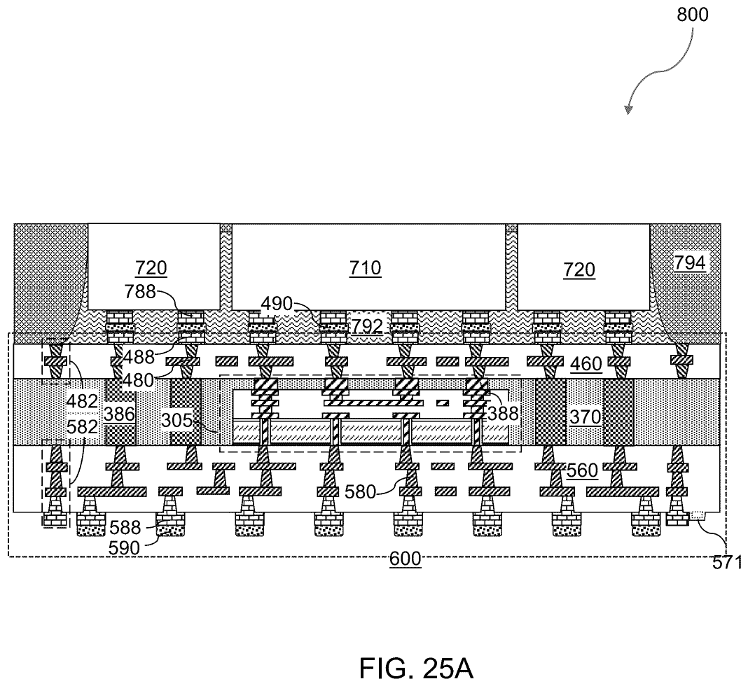

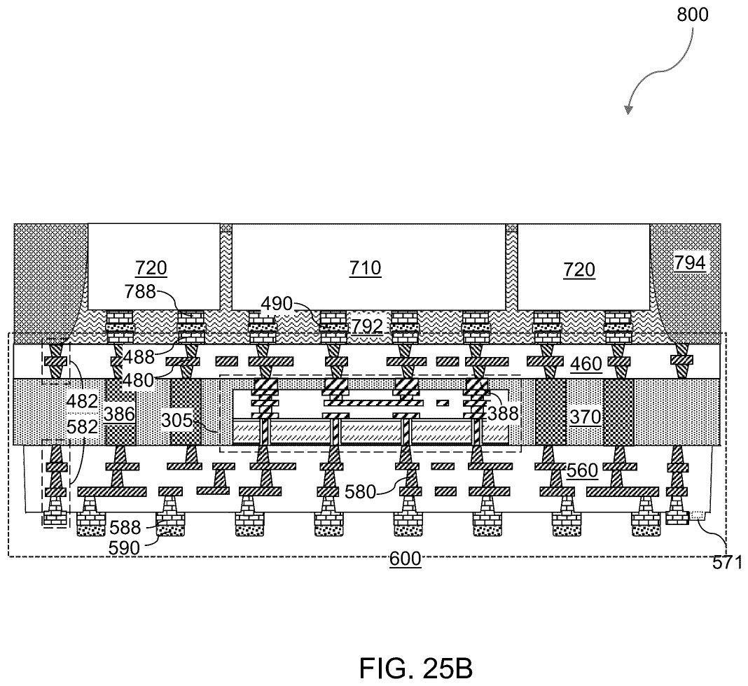

Referring to FIGS. 25A and 24B, the reconstituted wafer may be diced into composite dies along dicing channels by performing a dicing process. The dicing channels correspond to the boundaries between neighboring pairs of organic interposer dies 600. Each diced unit from the reconstituted wafer comprises a composite die, which is a fan-out package 800. Thus, each fan-out package 800 comprises an assembly of an organic interposer die 600, at least one semiconductor die (710, 720), an array of die-side solder material portions 490, a die-interposer underfill material portion 792, and a die-level molding compound matrix 794, which is a die-level molding compound frame.

FIG. 25A is a vertical cross-sectional view of an exemplary composite die according to an embodiment of the present disclosure. FIG. 25B is an additional vertical cross-sectional view for some configurations of the exemplary composite die according to an embodiment of the present disclosure. The view of FIG. 25A is common across all configurations of the exemplary structure as described with reference to FIGS. 15A-20B. The view of FIG. 25B may be generated from the fourth, fifth, and sixth configurations of the exemplary structure as described with reference to FIGS. 18A-20B, i.e., for configurations in which lithographically unilluminated areas are present in the distal redistribution dielectric layers 560, and thus, local trenches 589 are formed in the kerf areas 2000. In the configurations illustrated in FIG. 25B, the local trenches intersect the dicing channels, and thus, are manifested as sidewalls of the distal redistribution dielectric layers 560 that are laterally offset from the dicing planes which coincide with sidewalls of the molding compound matrix 370, the proximal redistribution dielectric layers 460, and the die-level molding compound matrix 794.

Generally, the sidewalls of the molding compound matrix 370, the proximal redistribution dielectric layers 460, and the die-level molding compound matrix 794 are vertically coincident in each organic interposer die 600. The distal redistribution dielectric layers 560 may comprise first sidewalls that are vertically coincident with the sidewalls of the molding compound matrix 370, the proximal redistribution dielectric layers 460, and the die-level molding compound matrix 794, and may, or may not, comprise second sidewalls that are laterally offset from the sidewalls of the molding compound matrix 370, the proximal redistribution dielectric layers 460, and the die-level molding compound matrix 794 depending on the configuration.

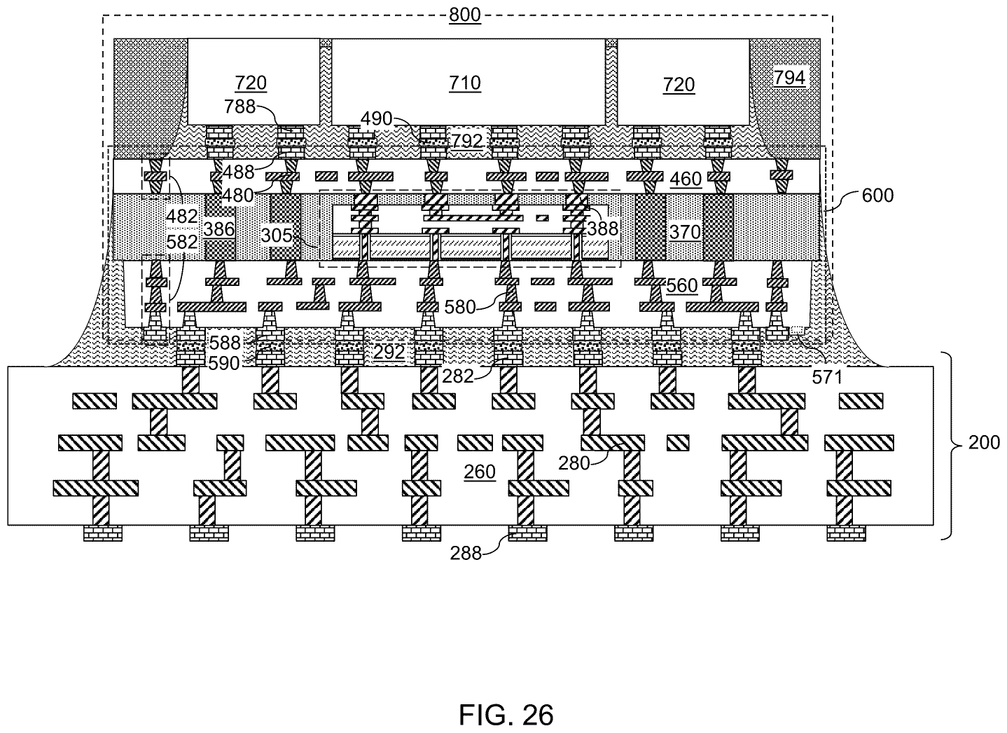

Referring to FIG. 26, a packaging substrate 200 may be provided. The packaging substrate 200 may be a cored packaging substrate including a core substrate, or a coreless packaging substrate that does not include a package core. Alternatively, the packaging substrate 200 may include a system-on-integrated packaging substrate (SoIS) including redistribution layers, dielectric interlayers, and/or at least one embedded interposer (such as a silicon interposer). Such a system-integrated packaging substrate may include layer-to-layer interconnections using solder material portions, microbumps, underfill material portions (such as molded underfill material portions), and/or an adhesion film. It is understood that the scope of the present disclosure is not limited by any particular type of substrate package. For example, an SoIS may be used in lieu of a cored packaging substrate. In embodiments in which SoIS is used, the core substrate may include a glass epoxy plate including an array of through-plate holes.

In one embodiment, the packaging substrate 200 may comprise substrate redistribution dielectric layers 260 having formed within substrate redistribution wiring interconnects 280. In one embodiment, the packaging substrate 200 may include board-side surface laminar circuit (SLC) and a chip-side surface laminar circuit (SLC). An array of package-side bonding pads 282 may be provided on the side of the packaging substrate 200 that faces the fan-out package 800. An array of board-side bonding pads 288 may be formed on the side of the packaging substrate 200 that is subsequently connected to a printed circuit board. The array of board-side bonding pads 288 is configured to allow bonding through solder joints having a greater dimension than the C4 solder balls.

The assembly including the fan-out package 800 may be attached to the packaging substrate 200 using an array of solder balls 290. Specifically, each of the solder balls 290 may be bonded to a respective one of the distal bump structures 588 and to a respective one of package-side bonding pads 282. A reflow process may be performed to reflow the solder balls 290 during the bonding process.

An underfill material may be applied into a gap between the proximal redistribution structure 400 and the packaging substrate 200. The underfill material may comprise any underfill material known in the art. An underfill material portion may be formed around the array of solder balls 290 in the gap between the proximal redistribution structure 400 and the packaging substrate 200. This underfill material portion is formed between the proximal redistribution structure 400 and the packaging substrate 200, and thus, is herein referred to as an interposer-package underfill material portion 292, or as an IP underfill material portion 292.

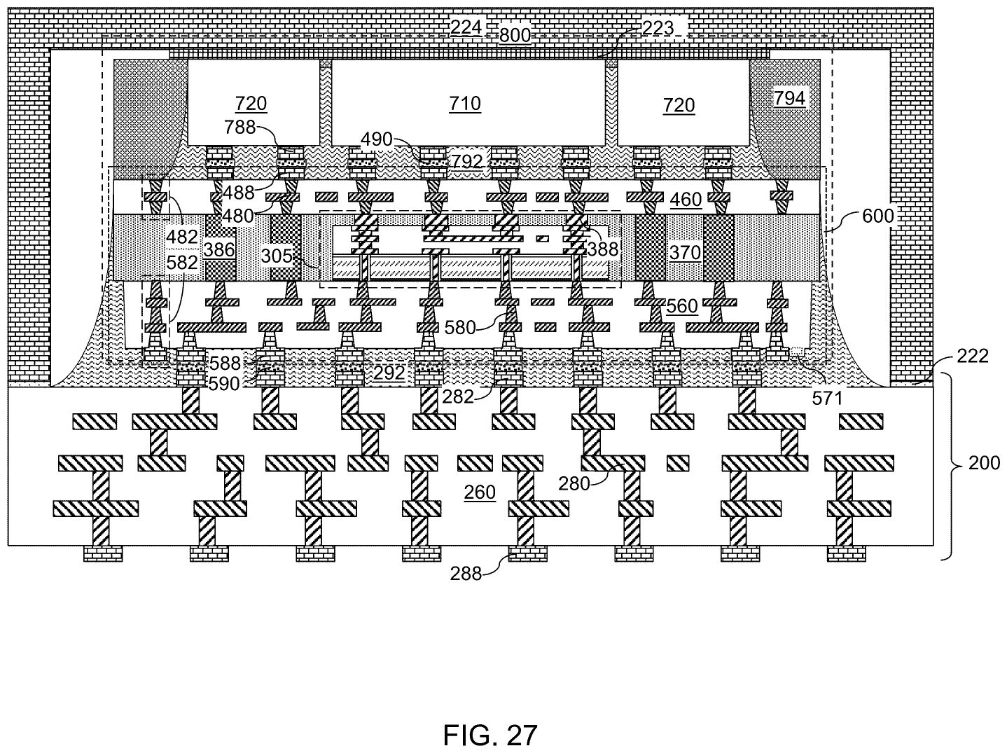

Referring to FIG. 27, a heat sink structure 224 may be attached to the top surfaces of the at least one semiconductor die (710, 720). In one embodiment, an adhesive layer 222 may be used to attach the heat sink structure 224 to a frame-shaped top surface segment of the packaging substrate 200. A thermal interface material (TIM) layer 223 may be formed between the at least one semiconductor die (710, 720) and the heat sink structure 224 to facilitate heat transfer from the at least one semiconductor die (710, 720) tot the heat sink structure 224.

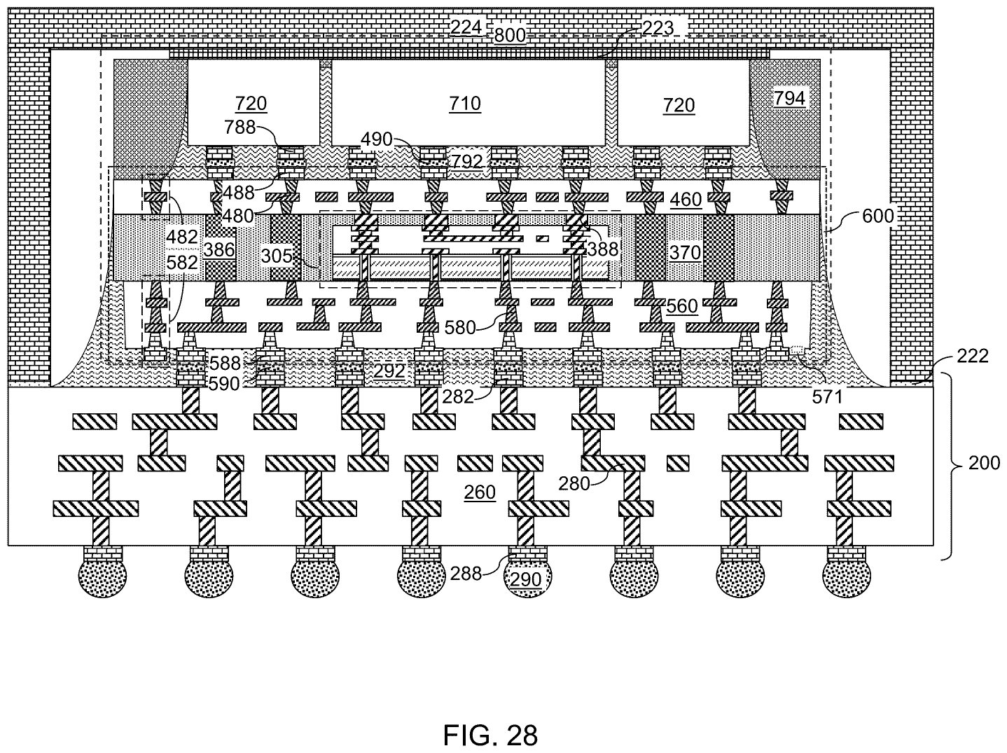

Referring to FIG. 28, solder balls 290 may be attached to the board-side bonding pads 288.

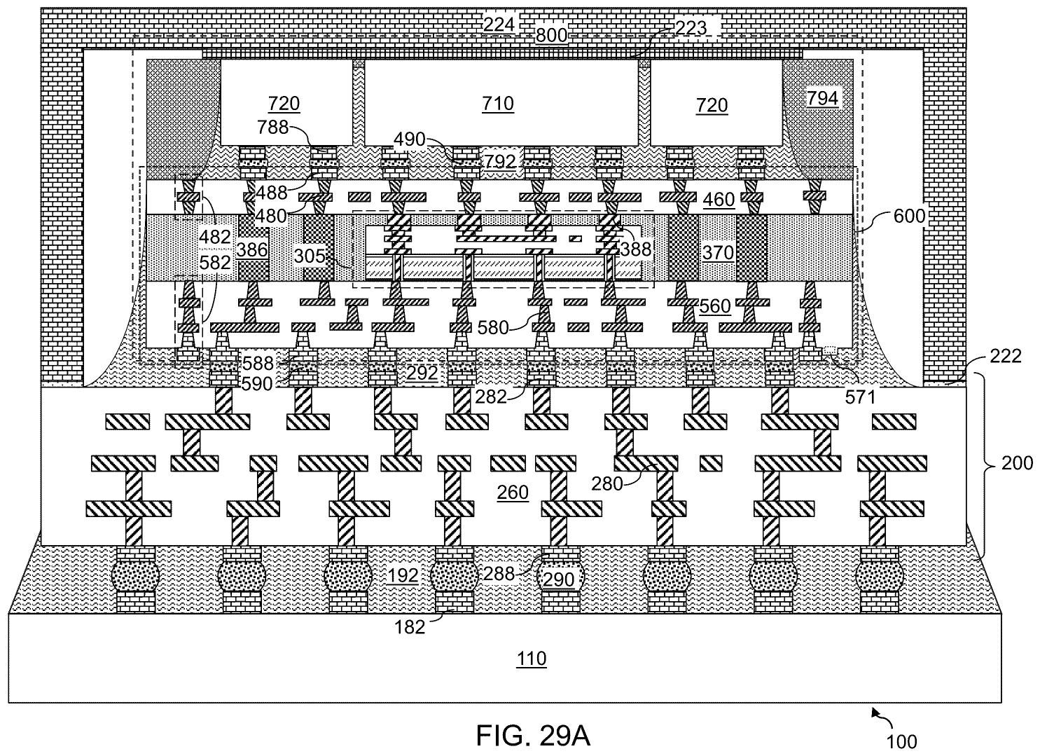

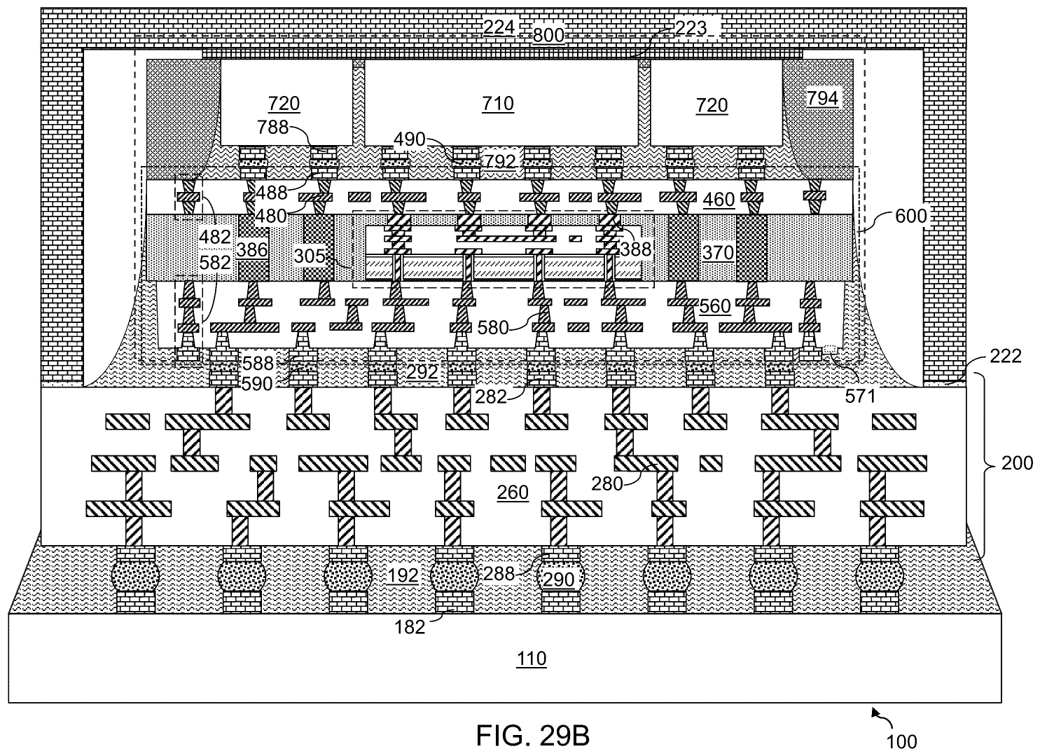

Referring to FIGS. 29A and 29B, a printed circuit board (PCB) 100 including a PCB substrate 110 and PCB bonding pads 182 may be provided. The PCB 100 includes a printed circuitry (not shown) at least on one side of the PCB substrate 110. Solder joints may be formed by disposing the array of solder balls 290 on the array of PCB bonding pads 182, and by reflowing the array of solder balls 290. An additional underfill material portion, which is herein referred to as a board-substrate underfill material portion 192 or a BS underfill material portion 192, may be formed around the solder balls 290 by applying and shaping an underfill material. The packaging substrate 200 is attached to the PCB 100 through the array of solder balls 290.

FIG. 29A is a vertical cross-sectional view of an exemplary composite die according to an embodiment of the present disclosure. FIG. 29B is an additional vertical cross-sectional view for some configurations of the exemplary composite die according to an embodiment of the present disclosure. The view of FIG. 29A is common across all configurations of the exemplary structure as described with reference to FIGS. 15A-20B. The view of FIG. 29B may be generated from the fourth, fifth, and sixth configurations of the exemplary structure as described with reference to FIGS. 18A-20B, i.e., for configurations in which lithographically unilluminated areas are present in the distal redistribution dielectric layers 560, and thus, local trenches 589 are formed in the kerf areas 2000.

Referring collectively to FIGS. 1-29B and according to various embodiments of the present disclosure, a package structure is provided, which comprises: an organic interposer die 600 comprising proximal redistribution dielectric layers 460 having formed therein proximal redistribution wiring interconnects 480, distal redistribution dielectric layers 560 composed of dielectric negative photoresist materials and having formed therein distal redistribution wiring interconnects 580 and an edge seal ring structure 582 that encloses a laterally-sealed area and is laterally surrounded by an enclosure wall portion of the distal redistribution dielectric layers 560, and proximal bump structures 488 connected to the proximal redistribution wiring interconnects 480; and at least one semiconductor die (710, 720) comprising on-die bump structures 788 that are bonded to the proximal bump structures 488, wherein: the enclosure wall portion of the distal redistribution dielectric layers 560 comprises a first region having a first thickness t1 and second regions having a second thickness t2 that is greater than the first thickness t1, wherein each of the second regions comprises a respective first uniform-height protrusion having a first uniform width.

In one embodiment, the enclosure wall portion of the distal redistribution dielectric layers 560 comprises third regions having a third thickness t3 that is greater than the second thickness t2 and having a second uniform-height protrusion having a second uniform width, which may be the same as the first uniform width.

In one embodiment, the package structure comprises: a packaging substrate 200 which is bonded to the organic interposer die 600 through an array of solder material portions 590; and an underfill material portion 292 laterally surrounding the array of solder material portions 590 and contacting the a contoured bottom surface of the enclosure wall portion of the distal redistribution dielectric layers 560, wherein all surfaces of the first uniform-height protrusion are in contact with the underfill material portion 292.

In one embodiment, the organic interposer die 600 comprises an interposer core layer 300 containing a molding compound matrix 370 having formed therein at least one of a bridge die 305 and a set of through-integrated-fan-out-via (TIV) structures 386; and the underfill material portion 292 is in contact with a horizontal surface segment of the molding compound matrix 370 and with sidewalls of the enclosure wall portion of the distal redistribution dielectric layers 560.

In one embodiment, the first region of the enclosure wall portion of the distal redistribution dielectric layers 560 may comprise a laterally recessed sidewall segment which is laterally recessed relative to a pair of sidewall segments of the distal redistribution dielectric layers 560 that are vertically coincident with a sidewall of the molding compound matrix 370. The second regions of the enclosure wall portion of the distal redistribution dielectric layers 560 may have a sidewall that is contained within a vertical plane including a sidewall of the molding compound matrix 370, or may be laterally recessed inward relative to a vertical plane including a sidewall of the molding compound matrix 370. The entirety of the first region of the enclosure wall portion of the distal redistribution dielectric layer 560 may be formed as a single contiguous structure.

The total number of the second regions of the enclosure wall portion of the distal redistribution dielectric layer 560 may be 2 in the first configuration (described with reference to FIGS. 15A and 15B) and in the second configuration (described with reference to FIGS. 16A and 16B); may be 4 in the third configuration (described with reference to FIGS. 17A and 17B); may be 2 in the fourth configuration (described with reference to FIGS. 18A and 18B) and in the fifth configuration (described with reference to FIGS. 19A and 19B); or may be more than 2 (described with reference to FIGS. 20A and 20B) including 2 strip-shaped second regions and at least one half-frame-shaped second regions.

The total number of the at least one third region of the enclosure wall portion of the distal redistribution dielectric layer 560 may be 1 in the first configuration (described with reference to FIGS. 15A and 15B) and in the second configuration (described with reference to FIGS. 16A and 16B); may be 4 in the third configuration (described with reference to FIGS. 17A and 17B); may be 1 in the fourth configuration (described with reference to FIGS. 18A and 18B), in the fifth configuration (described with reference to FIGS. 19A and 19B), and in the sixth configuration (described with reference to FIGS. 20A and 20B).

Each of the various configurations for the illumination areas in an exposure field EF provides defect-free developed pattern for the distal redistribution dielectric layers 560 after development without formation of any pattern within the die pattern area 1000. The first, second, third, fourth, and fifth configurations provide a rework process window for formation of the distal bump structures 588 in embodiments in which initial patterning of the distal bump structures 588 is defective. The first, second, and third configurations provide strip-shaped pattens of the second regions having the second thickness t2 along dicing channels (i.e., scribe lines), which function as guide structures during dicing. The fourth, fifth, and sixth configurations provide guide structures for dicing including at least one trench, which provide at least one laterally recessed sidewall segment for the distal redistribution dielectric layers 560 upon dicing.

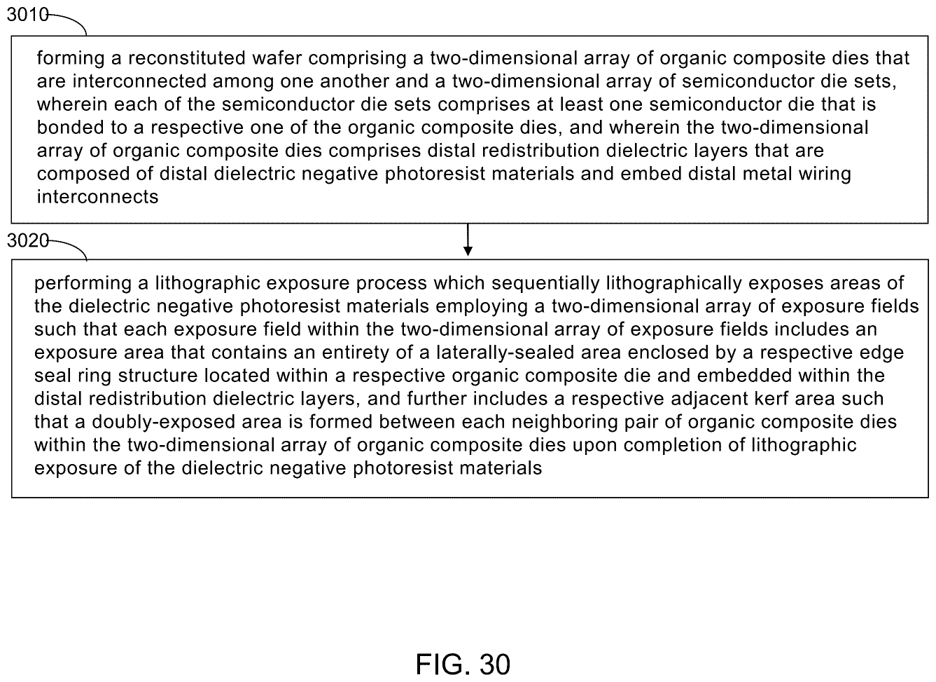

Referring to FIG. 30, a first flowchart illustrates steps for forming a device structure according to an embodiment of the present disclosure.

Referring to step 3010 and FIGS. 1-13, a reconstituted wafer is formed, which comprises a two-dimensional array of organic interposer dies 600 that are interconnected to one another and a two-dimensional array of semiconductor die sets (710, 720). Each of the semiconductor die sets (710, 720) comprises at least one semiconductor die (710, 720) that is bonded to a respective one of the organic interposer dies 600. The two-dimensional array of organic interposer dies 600 comprises distal redistribution dielectric layers 560 that are composed of dielectric negative photoresist materials and having formed therein distal redistribution wiring interconnects 580.

Referring to step 3020 and FIGS. 14-29B, a lithographic exposure process may be performed, which sequentially lithographically exposes areas of the dielectric negative photoresist materials using a two-dimensional array of exposure fields EF such that each exposure field EF within the two-dimensional array of exposure fields EF includes an illumination area that contains an entirety of a laterally-sealed area enclosed by a respective edge seal ring structure 582 located within a respective organic interposer die 600 and formed within the distal redistribution dielectric layers 560, and further includes a respective adjacent kerf area 2000 such that a double-exposed area 5702 is formed between each neighboring pair of organic interposer dies 600 within the two-dimensional array of organic interposer dies 600 upon completion of lithographic exposure of the dielectric negative photoresist materials.

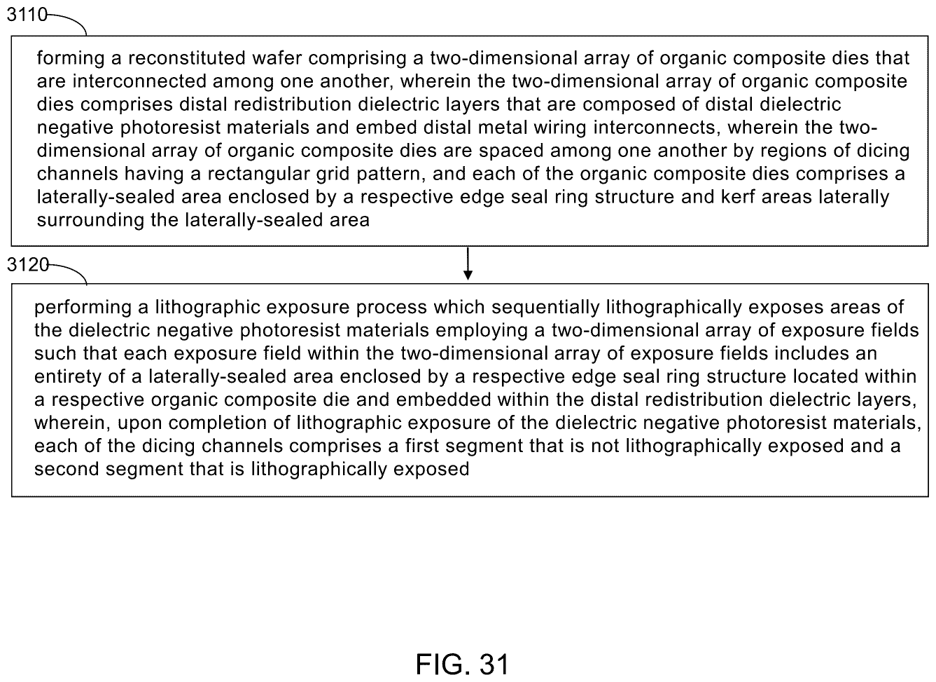

Referring to FIG. 31, a second flowchart illustrates steps for forming a device structure according to an embodiment of the present disclosure.

Referring to step 3110 and FIGS. 1-13, a reconstituted wafer is formed, which comprises a two-dimensional array of organic interposer dies 600 that are interconnected to one another and a two-dimensional array of semiconductor die sets (710, 720). The two-dimensional array of organic interposer dies 600 comprises distal redistribution dielectric layers 560 that are composed of dielectric negative photoresist materials and having formed therein distal redistribution wiring interconnects 580. The two-dimensional array of organic interposer dies 600 are spaced from one another by regions of dicing channels (which are center regions of the kerf areas 2000) having a rectangular grid pattern. Each of the organic interposer dies 600 comprises a laterally-sealed area enclosed by a respective edge seal ring structure 582 and kerf areas 2000 laterally surrounding the laterally-sealed area (which is a die pattern area 1000).

Referring to step 3120 and FIGS. 14-29B, a lithographic exposure process may be performed, which sequentially lithographically exposes areas of the dielectric negative photoresist materials using a two-dimensional array of exposure fields EF such that each exposure field EF within the two-dimensional array of exposure fields EF includes an entirety of a laterally-sealed area enclosed by a respective edge seal ring structure 582 located within a respective organic interposer die 600 and formed within the distal redistribution dielectric layers 560. Upon completion of lithographic exposure of the dielectric negative photoresist materials, at least one of the dicing channels between neighboring pairs of exposure fields EF comprises a first segment that is not lithographically exposed and a second segment that is lithographically exposed.

The various embodiments of the present disclosure prevent formation of unwanted trenches in distal redistribution dielectric layers 560 of organic interposer dies 600 due to overlay variations during lithographic exposure. By adjusting the layout of illuminated areas during lithographic exposure of the distal redistribution dielectric layers 560 to enhance exposure field alignment, the embodiment methods of the present disclosure removes the effects of overlay errors, leading to more consistent and defect-free distal redistribution dielectric layers 560. Embodiments of the present disclosure may be used to enhance the integrity and functionality of the organic interposer dies 600 in semiconductor manufacturing, and to enhance the reliability and yield of package structures.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph of in different paragraphs, a Markush group including a listing of the two or more elements may be also impliedly disclosed in some embodiments. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming a reconstituted wafer comprising a two-dimensional array of interposer dies that are interconnected to one another and a two-dimensional array of semiconductor die sets, wherein each of the semiconductor die sets comprises at least one semiconductor die that is bonded to a respective one of the two-dimensional array of interposer dies, and wherein the two-dimensional array of interposer dies comprises distal redistribution dielectric layers that are composed of dielectric negative photoresist materials and having formed therein distal redistribution wiring interconnects; and
performing a lithographic exposure process which sequentially lithographically exposes areas of the dielectric negative photoresist materials using a two-dimensional array of exposure fields such that each exposure field within the two-dimensional array of exposure fields includes an illumination area that contains an entirety of a laterally-sealed area enclosed by a respective edge seal ring structure located within a respective interposer die and formed within the distal redistribution dielectric layers, and further includes a respective adjacent kerf area such that a double-exposed area is formed between each neighboring pair of interposer dies within the two-dimensional array of interposer dies upon completion of lithographic exposure of the dielectric negative photoresist materials.

2. The method of claim 1, wherein the distal redistribution dielectric layers comprise:
a first distal redistribution dielectric layer having formed therein first distal redistribution wiring interconnects and comprising a first dielectric negative photoresist material; and
a terminal distal redistribution dielectric layer overlying the first distal redistribution dielectric layer, having formed therein terminal distal redistribution wiring interconnects, and comprising a terminal dielectric negative photoresist material, wherein distal bump structures are formed on the terminal distal redistribution wiring interconnects.

3. The method of claim 1, wherein:
the reconstituted wafer comprises an interposer core layer comprising at least one of a two-dimensional array of bridge dies, and a two-dimensional array of sets of through-integrated-fan-out-via (TIV) structures; and
the distal redistribution dielectric layers are formed over the interposer core layer.

4. The method of claim 3, wherein the interposer core layer comprises a first molding compound matrix which comprises a first non-photosensitive molding compound material.

5. The method of claim 3, wherein forming the reconstituted wafer comprises:
forming the interposer core layer over a first carrier wafer;
forming proximal redistribution dielectric layers and proximal bump structures over the interposer core layer, wherein the proximal redistribution dielectric layers having formed therein proximal redistribution wiring interconnects; and
attaching the two-dimensional array of semiconductor die sets to the proximal bump structures.

6. The method of claim 5, wherein forming the reconstituted wafer further comprises:
forming a molding compound matrix around the two-dimensional array of semiconductor die sets;
attaching a second carrier wafer to the molding compound matrix;
detaching the first carrier wafer from the interposer core layer; and
forming the distal redistribution dielectric layers and the distal redistribution wiring interconnects over the interposer core layer.

7. The method of claim 1, wherein:
each of the distal redistribution dielectric layers comprises a respective dielectric negative photoresist material; and
the lithographic exposure process lithographically exposes each dielectric negative photoresist material within the distal redistribution dielectric layers.

8. The method of claim 1, wherein:
dicing channels are present between neighboring pairs of the interposer dies within center regions of kerf areas that are located between neighboring pairs of the edge seal ring structures; and
lithographic exposure of an exposure field that includes an entire area within an edge seal ring structure of a selected interposer die forms one of the double-exposed areas within an area of the selected interposer die.

9. The method of claim 1, wherein:
dicing channels are present between neighboring pairs of the interposer dies within center regions of the kerf areas that are located between neighboring pairs of the edge seal ring structures; and
lithographic exposure of an exposure field that includes an entire area within an edge seal ring structure of a selected interposer die forms one of the double-exposed areas within an area of a neighboring interposer die that is laterally offset from the selected interposer die by one of the dicing channels.

10. The method of claim 1, wherein:
dicing channels are present between neighboring pairs of the interposer dies within center regions of the kerf areas that are located between neighboring pairs of the edge seal ring structures; and
one of the dicing channels between neighboring pairs of exposure fields comprises a segment that is located between a respective neighboring pair of interposer dies and is not lithographically exposed upon completion of the lithographic exposure of the dielectric negative photoresist materials.

11. The method of claim 10, wherein one of the dicing channels between neighboring pairs of exposure fields comprises an additional segment that is located between the respective neighboring pair of interposer dies and is lithographically exposed upon completion of the lithographic exposure of the dielectric negative photoresist materials.

12. A method of forming a device structure, comprising:
forming a reconstituted wafer comprising a two-dimensional array of interposer dies that are interconnected to one another, wherein the two-dimensional array of interposer dies comprises distal redistribution dielectric layers that are composed of dielectric negative photoresist materials and having formed therein distal redistribution wiring interconnects, wherein the two-dimensional array of interposer dies are spaced from one another by regions of dicing channels having a rectangular grid pattern, and each of the interposer dies comprises a laterally-sealed area enclosed by a respective edge seal ring structure and kerf areas laterally surrounding the laterally-sealed area; and
performing a lithographic exposure process which sequentially lithographically exposes areas of the dielectric negative photoresist materials using a two-dimensional array of exposure fields such that each exposure field within the two-dimensional array of exposure fields includes an entirety of a laterally-sealed area enclosed by a respective edge seal ring structure located within a respective interposer die and formed within the distal redistribution dielectric layers, wherein, upon completion of lithographic exposure of the dielectric negative photoresist materials, one of the dicing channels between neighboring pairs of exposure fields comprises a first segment that is not lithographically exposed and a second segment that is lithographically exposed.

13. The method of claim 12, wherein a double-exposed area is formed between each neighboring pair of interposer dies in a respective one of the kerf areas within the two-dimensional array of interposer dies upon completion of lithographic exposure of the dielectric negative photoresist materials.

14. The method of claim 13, wherein a two-dimensional array of quadruple-exposed areas is formed in proximity to intersection locations of the rectangular grid pattern of the dicing channels within the kerf areas of the two-dimensional array of interposer dies.

15. The method of claim 12, wherein the first segment is laterally surrounded by a double-exposed area that is lithographically exposed twice during the lithographic exposure of the dielectric negative photoresist materials.

16. The method of claim 12, wherein areas of illumination within each exposure field comprises a primary illumination area that includes the laterally-sealed area of a selected interposer die and further comprises an auxiliary illumination area located within a neighboring interposer die that is located adjacent to the selected interposer die, wherein a strip-shaped gap located between the primary illumination area and the auxiliary illumination area is not illuminated during lithographic exposure of the selected interposer die.

17. A package structure comprising:
an interposer die comprising proximal redistribution dielectric layers having formed therein proximal redistribution wiring interconnects, distal redistribution dielectric layers composed of dielectric negative photoresist materials and having formed therein distal redistribution wiring interconnects and an edge seal ring structure that encloses a laterally-sealed area and is laterally surrounded by an enclosure wall portion of the distal redistribution dielectric layers, and proximal bump structures connected to the proximal redistribution wiring interconnects; and
at least one semiconductor die comprising on-die bump structures that are bonded to the proximal bump structures, wherein:
the enclosure wall portion of the distal redistribution dielectric layers comprises a first region having a first thickness and second regions having a second thickness that is greater than the first thickness, wherein each of the second regions comprises a respective first uniform-height protrusion having a uniform width.

18. The package structure of claim 17, wherein the enclosure wall portion of the distal redistribution dielectric layers comprises third regions having a third thickness that is greater than the second thickness.

19. The package structure of claim 17, further comprising:
a packaging substrate which is bonded to the interposer die through an array of solder material portions; and
an underfill material portion laterally surrounding the array of solder material portions and contacting the a contoured bottom surface of the enclosure wall portion of the distal redistribution dielectric layers, wherein all surfaces of the first uniform-height protrusion are in contact with the underfill material portion.

20. The package structure of claim 19, wherein:
the interposer die comprises an interposer core layer containing a molding compound matrix having disposed therein at least one of a bridge die and a set of through-integrated-fan-out-via (TIV) structures; and
the underfill material portion is in contact with a horizontal surface segment of the molding compound matrix and with sidewalls of the enclosure wall portion of the distal redistribution dielectric layers.
